(19) United States
(12) Patent Application Publication
(10) Pub. No.: US 2026/0123230 A1
(43) Pub. Date: Apr. 30, 2026

(54) DISPLAY PANEL AND DISPLAY DEVICE

(71) Applicant: Hubei Yangtze Industrial Innovation Center Of Advanced Display Co., Ltd., Wuhan (CN)

(72) Inventors: Dandan ZANG, Wuhan (CN); Yanzi LIU, Wuhan (CN); Liang HU, Wuhan (CN); Lilian KUANG, Wuhan (CN)

(73) Assignee: Hubei Yangtze Industrial Innovation Center Of Advanced Display Co., Ltd., Wuhan (CN)

(21) Appl. No.: 19/432,553

(22) Filed: Dec. 24, 2025

(30) Foreign Application Priority Data
Dec. 30, 2024 (CN) 202411979371.9

(51) Int. Cl. H10K 59/38; H10K 59/122; H10K 59/126; H10K 59/131; H10K 59/35; H10K 59/80; H10K 102/00

(52) U.S. Cl. CPC H10K 59/38; H10K 59/122; H10K 59/126; H10K 59/131; H10K 59/353; H10K 59/80515; H10K 2102/351

(57) ABSTRACT

Provided are a display panel and a display device. The display panel includes a display region and a first region located within the display region. The display region includes a substrate, a pixel definition layer, multiple light-emitting elements, and a light-blocking layer that are disposed sequentially. The pixel definition layer has multiple first openings. The light-blocking layer has multiple second openings. The light-emitting elements are located in the first openings respectively. The light-blocking layer in the first region further has at least one third opening. Along the first direction, the second openings overlap the first openings respectively, and the at least one third opening does not overlap the first openings. The first direction is parallel to a stacking direction of film layers in the display region.

### CROSS-REFERENCE TO RELATED APPLICATION

This application claims priority to Chinese Patent Application No. 202411979371.9, filed on Dec. 30, 2024, the disclosure of which is incorporated herein by reference in its entirety.

### TECHNICAL FIELD

The present disclosure relates to the technical field of display panels and, in particular, to a display panel and a display device.

### BACKGROUND

With the continuous development of display technology, display panels have been widely applied in production and life. However, display panels in the related art still have some technical problems to be solved urgently.

For example, users have a demand for full screens. However, most existing display panels have a hole punched in a display region, resulting in a low screen-to-body ratio or a black hole in the display region and thereby affecting the display effect.

### SUMMARY

The present disclosure provides a display panel and a display device to increase the screen-to-body ratio of the display panel and achieve a full screen.

According to an aspect of the present disclosure, a display panel is provided. The display panel includes a display region and a first region located within the display region.

The display region includes a substrate, a pixel definition layer, a plurality of light-emitting elements, and a light-blocking layer that are disposed sequentially; the pixel definition layer has a plurality of first openings, and the light-blocking layer has a plurality of second openings; the plurality of light-emitting elements are located in the plurality of first openings respectively.

The light-blocking layer in the first region further has at least one third opening.

Along a first direction, the plurality of second openings overlap the plurality of first openings respectively, and the at least one third opening does not overlap the plurality of first openings; the first direction is parallel to a stacking direction of film layers in the display region.

According to another aspect of the present disclosure, a display device is provided. The display device includes the preceding display panel.

It is to be understood that the content described in this section is neither intended to identify key or critical features of embodiments of the present disclosure nor intended to limit the scope of the present disclosure. Other features of the present disclosure become easily understood through the description provided hereinafter.

### BRIEF DESCRIPTION OF DRAWINGS

To illustrate the technical solutions in embodiments of the present disclosure more clearly, drawings used in the description of the embodiments are briefly described hereinafter. Apparently, the drawings described hereinafter illustrate part of the embodiments of the present disclosure, and those of ordinary skill in the art may obtain other drawings based on the drawings described hereinafter on the premise that no creative work is done.

FIG. 1 is a diagram of a display panel according to an embodiment of the present disclosure.

FIG. 2 is another diagram of a display panel according to an embodiment of the present disclosure.

FIG. 3 is yet another diagram of a display panel according to an embodiment of the present disclosure.

FIG. 4 is a partial top view of a first region in FIG. 3.

FIG. 5 is yet another diagram of a display panel according to an embodiment of the present disclosure.

FIG. 6 is a partial top view of a first region in FIG. 5.

FIG. 7 is yet another diagram of a display panel according to an embodiment of the present disclosure.

FIG. 8 is a partial top view of a first region in FIG. 7.

FIG. 9 is yet another diagram of a display panel according to an embodiment of the present disclosure.

FIG. 10 is a partial top view of a first region in FIG. 9.

FIG. 11 is yet another diagram of a display panel according to an embodiment of the present disclosure.

FIG. 12 is a partial top view of a first region in FIG. 11.

FIG. 13 is yet another diagram of a display panel according to an embodiment of the present disclosure.

FIG. 14 is a partial top view of a first region in FIG. 13.

FIG. 15 is yet another diagram of a display panel according to an embodiment of the present disclosure.

FIG. 16 is a partial top view of a pixel definition layer in FIG. 15.

FIG. 17 is yet another diagram of a display panel according to an embodiment of the present disclosure.

FIG. 18 is a partial top view of a pixel definition layer in FIG. 17.

FIG. 19 is another partial top view of a pixel definition layer in FIG. 17.

FIG. 20 is yet another partial top view of a pixel definition layer in FIG. 17.

FIG. 21 is yet another diagram of a display panel according to an embodiment of the present disclosure.

FIG. 22 is yet another diagram of a display panel according to an embodiment of the present disclosure.

FIG. 23 is yet another diagram of a display panel according to an embodiment of the present disclosure.

FIG. 24 is yet another diagram of a display panel according to an embodiment of the present disclosure.

FIG. 25 is a partial cross-sectional view taken along F31-F32 of FIG. 24.

FIG. 26 is a diagram of a pixel circuit according to an embodiment of the present disclosure.

FIG. 27 is yet another diagram of a display panel according to an embodiment of the present disclosure.

FIG. 28 is yet another diagram of a display panel according to an embodiment of the present disclosure.

FIG. 29 is yet another diagram of a display panel according to an embodiment of the present disclosure.

FIG. 30 is a diagram of a display device according to an embodiment of the present disclosure.

### DETAILED DESCRIPTION

To make the technical solutions of the present disclosure better understood by those skilled in the art, the technical solutions in the embodiments of the present disclosure are described hereinafter clearly and completely in conjunction with the drawings in the embodiments of the present disclosure. Apparently, the embodiments described hereinafter are part, not all, of the embodiments of the present disclosure. Based on the embodiments of the present disclosure, all other embodiments obtained by those of ordinary skill in the art are within the scope of the present disclosure on the premise that no creative work is done.

It is to be noted that terms such as “first” and “second” in the description, claims, and drawings of the present disclosure are used for distinguishing between similar objects and are not necessarily used for describing a particular order or sequence. It is to be understood that data used in this manner are interchangeable where appropriate so that the embodiments of the present disclosure described herein can be implemented in an order not illustrated or described herein. In addition, terms “comprising”, “including” and any variation thereof are intended to encompass a non-exclusive inclusion. For example, a process, method, system, product, or device that includes a series of steps or units not only includes the expressly listed steps or units, but may also include other steps or units that are not expressly listed or are inherent to such a process, method, product, or device.

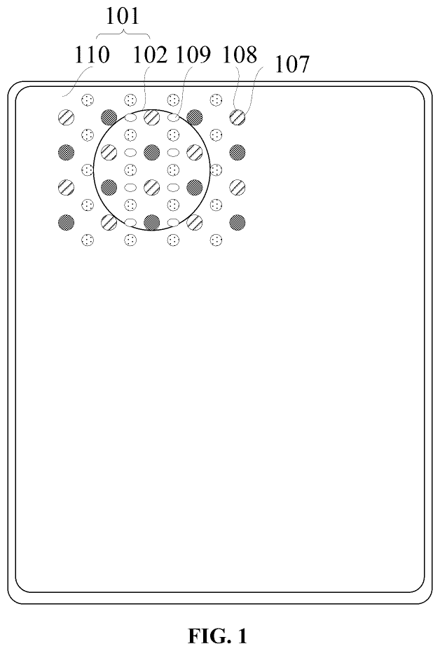

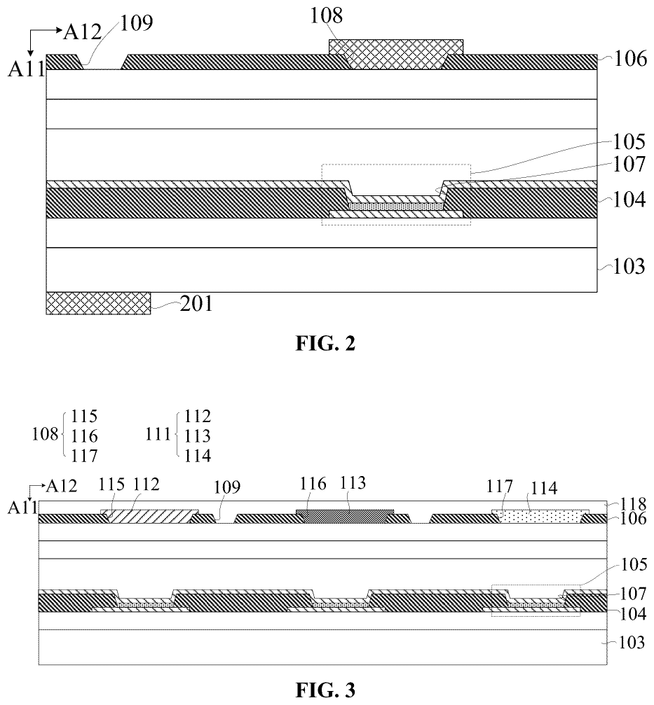

FIG. 1 is a diagram of a display panel according to an embodiment of the present disclosure. FIG. 2 is another diagram of a display panel according to an embodiment of the present disclosure. This embodiment is applicable to any situation where the transmittance of the display panel is increased. As shown in FIGS. 1 and 2, the display panel includes a display region 101 and a first region 102 located within the display region 101. The display region 101 includes a substrate 103, a pixel definition layer 104, multiple light-emitting elements 105, and a light-blocking layer 106 that are disposed sequentially. The pixel definition layer 104 has multiple first openings 107. The light-blocking layer 106 has multiple second openings 108. The light-emitting elements 105 are located in the first openings 107 respectively. The light-blocking layer 106 in the first region 102 further has at least one third opening 109. Along the first direction A11, the second openings 108 overlap the first openings 107 respectively, and the at least one third opening 109 does not overlap the first openings 107. The first direction A11 is parallel to a stacking direction of film layers in the display region 101. In an embodiment, FIG. 2 shows a partial section of the display panel along the first direction A11, including one third opening 109, the second opening 108, and the first opening 107, wherein the second opening 108 and the first opening 107 face each other.

In this embodiment, the display panel includes the display region 101, and the display region 101 is configured to display images.

The display panel includes the substrate 103. The substrate 103 is a multilayer stacking structure, and the specific film layer structure of the substrate 103 is not described in detail in this embodiment. The first direction A11 is parallel to the film layer stacking direction in the substrate 103, and the first direction A11 and the second direction A12 intersect. Here, optionally, the first direction A11 and the second direction A12 intersect perpendicularly.

The display panel includes the pixel definition layer 104. The pixel definition layer 104 is located on a side of the substrate 103 along the first direction A11. Within the display region 101, the pixel definition layer 104 has the multiple first openings 107, the multiple first openings 107 correspond to the multiple light-emitting elements 105 respectively, and the light-emitting elements 105 are located in the corresponding first openings 107 respectively. In an embodiment, the light-emitting elements 105 fill the corresponding first openings 107 respectively; along the first direction A11, optionally, the light-emitting elements 105 cover the corresponding first openings 107 respectively, and the first openings 107 define light-emitting regions of the corresponding light-emitting elements 105 respectively. Optionally, the pixel definition layer 104 is a black pixel definition layer (BPDL), and the black pixel definition layer is made of a black material, which can reduce the reflection of light within the display panel and improve the display effect. However, it is not limited to this. If required by a product, the pixel definition layer may also be a non-black pixel definition layer.

The display panel includes the multiple light-emitting elements 105. The multiple light-emitting elements 105 may be divided into three categories, namely multiple first light-emitting elements, multiple second light-emitting elements, and multiple third light-emitting elements. The first light-emitting elements, the second light-emitting elements, and the third light-emitting elements may be different in color configured. Exemplarily, the first light-emitting elements may be red light-emitting elements, the second light-emitting elements may be blue light-emitting elements, and the third light-emitting elements may be green light-emitting elements. However, it is not limited to this. Relevant practitioners may reasonably configure the colors of the first light-emitting elements, the second light-emitting elements, and the third light-emitting elements according to the requirements of the product. The color of the first light-emitting elements, the color of the second light-emitting elements, and the color of the third light-emitting elements may be the same, may not be completely the same, may be completely different, and the like.

The display panel includes the light-blocking layer 106. The light-blocking layer 106 is located on a side of the pixel definition layer 104 facing away from the substrate 103 and can block light. Within the display region 101, the light-blocking layer 106 has the multiple second openings 108, and the second openings 108 are structures that do not block light. The multiple second openings 108 correspond to the multiple light-emitting elements 105 respectively. Along the first direction A11, the orthographic projections of the second openings 108 on the pixel definition layer 104 overlap the corresponding first openings 107 respectively. In an embodiment, optionally, along the first direction A11, the orthographic projections of the second openings 108 on the pixel definition layer 104 cover the corresponding first openings 107 respectively, and light emitted from the light-emitting regions of the light-emitting elements 105 defined by the first openings 107 can be emitted through the second openings 108 respectively. Optionally, the light-blocking layer 106 is a black matrix (BM), and the black matrix is made of a black material, which can reduce the reflection of light within the display panel, block the large-angle light emitted by the light-emitting elements 105, and prevent external light from entering the display panel, thereby improving the display effect.

It is to be understood that there are other film layer structures between the substrate 103 and the pixel definition layer 104, and there are other film layer structures between the pixel definition layer 104 and the light-blocking layer 106, which are not shown in FIG. 2, and some film layers are explained in detail in subsequent embodiments.

The display region 101 includes the first region 102, and a region other than the first region 102 in the display region 101 is defined as a second region 110. The display region 101 is configured for display, and the corresponding first region 102 and the second region 110 can display. The distribution density of light-emitting elements 105 in the second region 110 may be the same as or different from the distribution density of light-emitting elements 105 in the first region 102, and the arrangement mode of the multiple light-emitting elements 105 in the second region 110 may be the same as or different from the arrangement mode of the multiple light-emitting elements 105 in the first region 102. In an embodiment, optionally, the distribution density of the light-emitting elements 105 in the second region 110 is greater than or equal to the distribution density of the light-emitting elements 105 in the first region 102; and/or, optionally, the arrangement mode of the light-emitting elements 105 in the second region 110 is the same as the arrangement mode of the light-emitting elements 105 in the first region 102. A mark 102 shown in FIG. 1 is the orthographic projection of the first region 102 along the first direction A11.

The light-blocking layer 106 in the first region 102 has the at least one third opening 109; along the first direction A11, the at least one third opening 109 does not overlap the first openings 107. A third opening 109 is a structure that does not block light. Along the first direction A11, a region defined by the third opening 109 forms an additional light transmission region. Therefore, the at least one third opening 109 is added to the light-blocking layer 106 in the first region 102. Light passes through the at least one third opening 109, which can increase the transmittance of the first region 102. In an embodiment, for the conventional light-blocking layer, the transmittance of an opening region in an infrared light waveband (such as 940 nm) is greater than 80%, and the transmittance of a non-opening region in the infrared light waveband is less than 2%. In this embodiment, one or more third openings 109 are added to the original non-opening region of the light-blocking layer 106 in the first region 102 so that the area proportion of the opening region of the light-blocking layer 106 in the first region 102 can be increased; the transmittance of the third opening 109 in the infrared light waveband is greater than 80%, so the transmittance of the first region 102 in the infrared light waveband can be effectively increased. Since the first region 102 only has openings, namely third openings 109, newly dug in the original non-opening region of the light-blocking layer 106, the total area of the newly added third openings 109 accounts for a minimal proportion of the first region 102, an increase in the visible light reflectance of the corresponding first region 102 is minimal, and the first region 102 does not have a serious dark state visual effect so that a good display effect of the display panel can be ensured. In this embodiment, optionally, the first region 102 is used as an infrared transmitting region.

It is to be understood that the infrared light waveband is about 760 nm to 1000 nm, and the specific value of the infrared light transmittance described in the present disclosure is mainly the transmittance detected at 940 nm. Exemplarily, the transmittance of the third opening 109 in the infrared light waveband is greater than 80%, which actually means that the transmittance of the third opening 109 at 940 nm is greater than 80%.

In an embodiment, for any one of a first opening 107, a second opening 108, or the third opening 109, an upper opening, a lower opening, and an inner sidewall connected between the upper opening and the lower opening are included, where the upper opening is far away from the substrate 103, and the lower opening is adjacent to the substrate 103. Under normal circumstances, the inner sidewall of an opening has an inclined structure. Accordingly, the sectional shape of the opening along the first direction A11 should be an inverted trapezoid, that is, the upper opening has a large size, and the lower opening has a small size. In an embodiment, the area of the upper opening of the opening is larger than the area of the lower opening of the opening. Mark 107 shown in FIG. 1 denotes the orthographic projection of a lower opening of the first opening 107 along the first direction A11, and a region defined by a lower opening of the first opening 107 is a light-emitting region of the corresponding light-emitting element 105. Mark 108 shown in FIG. 1 denotes the orthographic projection of a lower opening of the second opening 108 along the first direction A11, and a region defined by the lower opening of the second opening 108 is a light transmission region of the corresponding light-emitting element 105. FIG. 1 shows the overlapping relationship between the first opening 107 and the second opening 108, which does not represent the actual size relationship. The relationship between the first opening 107 and the second opening 108 may be designed as “greater than”, “less than”, or “equal to” according to the requirements of the product. Mark 109 shown in FIG. 1 denotes the orthographic projection of a lower opening of the third opening 109 along the first direction A11. The region defined by the lower opening of the third opening 109 is a newly added light transmission region of the first region 102. The newly added light transmission region is configured not to transmit the light emitted by the light-emitting element 105.

Optionally, the first region 102 includes a first function device 201 located on a side of the substrate 103 facing away from the light-blocking layer 106; along the first direction A11, the at least one third opening 109 overlaps the first function device 201. Here, optionally, the first function device 201 includes an optical device.

The optical device may be disposed in the first region 102 to increase the screen-to-body ratio and meet the users' requirements for a full screen. Exemplarily, the optical devices such as a camera, a face recognition sensor, a fingerprint recognition sensor, and an infrared light sensor may be disposed in the first region 102.

In this embodiment, optionally, the first region 102 is used as the infrared transmitting region; optionally, the first function device 201 is an infrared light sensor, which can receive and send infrared light. The first region 102 can display normally, and the at least one third opening 109 is added to the light-blocking layer 106 of the first region 102, which can also increase the light transmittance of the first region 102 and increase the light passing through the first region 102 so that the first region 102 can fulfill the light transmission function, meet the photosensitive requirements of the optical devices in the first region 102, and increase the optical detection accuracy of the optical devices.

It is to be noted that the first region 102 in the display panel may be in the shape of a circle, an ellipse, a square, or others, and FIG. 1 shows that the first region 102 is in the shape of a circle. Optionally, the third opening is in the shape of a polygon or a circle, which is not limited to this. Exemplarily, the third opening may also be in the shape of an ellipse, a square, or others, and FIG. 1 shows that the third opening 109 is in the shape of an ellipse.

In the present disclosure, the display region includes the first region, and the light-blocking layer in the first region has the at least one third opening; along the first direction, the at least one third opening does not overlap the first openings, and the third opening is a structure that does not block light, so the region defined by the third opening in the first region is a newly added light transmission region so that the light can be allowed to pass through the third opening, thereby increasing the transmittance of the first region. Since the opening, namely the third opening, is newly dug only in the light-blocking layer in the first region, the increase in the visible light reflectance of the first region is minimal, and the third opening does not cause a serious dark state visual effect in the first region. Based on this, newly digging the third opening in the light-blocking layer in the first region can increase the transmittance of the first region, allow the third opening to have little impact on the display effect of the display panel, and also ensure a high screen-to-body ratio of the display panel so that the full screen can be achieved, and the display effect can be improved.

FIG. 3 is yet another diagram of a display panel according to an embodiment of the present disclosure. FIG. 4 is a partial top view of a first region in FIG. 3. As shown in FIGS. 3 and 4, optionally, the display region 101 further includes a color filter layer 111 located on a side of the light-blocking layer 106 facing away from the pixel definition layer 104. The color filter layer 111 includes a first color filter 112, a second color filter 113, and a third color filter 114. The second openings 108 include a first color filter opening 115, a second color filter opening 116, and a third color filter opening 117. The first color filter 112 is at least located in the first color filter opening 115, the second color filter 113 is located in the second color filter opening 116, and the third color filter 114 is located in the third color filter opening 117. Any one of the second openings 108 or the third openings 109 shown in FIG. 4 is the lower opening thereof.

In this embodiment, the display panel further includes the color filter layer 111. The color filter layer 111 includes multiple color filters. The multiple color filters may be divided into three categories, namely multiple first color filters 112, multiple second color filters 113, and multiple third color filters 114. The colors configured for the first color filters 112, the second color filters 113, and the third color filters 114 are different. Optionally, the first color filter 112 is a red color filter; the second color filter 113 is one of a green color filter or a blue color filter, and the third color filter 114 is the other one of the green color filter or the blue color filter. Exemplarily, the first color filter 112 is a red color filter, the second color filter 113 is a blue color filter, and the third color filter 114 is a green color filter. Exemplarily, the first color filter 112 is a red color filter, the second color filter 113 is a green color filter, and the third color filter 114 is a blue color filter. However, it is not limited to this, and the relevant practitioners may reasonably configure the colors of the first color filter, the second color filter, and the third color filter according to the requirements of the product.

Optionally, at least one of the first color filter 112, the second color filter 113, or the third color filter 114 is each in the shape of a circle. Optionally, in FIG. 4, the first color filter 112, the second color filter 113, and the third color filter 114 are in the shape of a circle, but are not limited to this.

In the light-blocking layer 106, the multiple second openings 108 include multiple first color filter openings 115, multiple second color filter openings 116, and multiple third color filter openings 117. The first color filters 112 are at least located in the first color filter openings 115 respectively, the second color filters 113 are located in the second color filter openings 116 respectively, and the third color filters 114 are located in the third color filter openings 117 respectively. In an embodiment, the first color filters 112 at least fill the corresponding first color filter openings 115 respectively, and along the first direction A11, the first color filters 112 cover the corresponding first color filter openings 115 respectively; the second color filters 113 at least fill the corresponding second color filter openings 116 respectively, and along the first direction A11, the second color filters 113 cover the corresponding second color filter openings 116 respectively; the third color filters 114 fill the corresponding third color filter openings 117 respectively, and along the first direction A11, the third color filters 114 cover the corresponding third color filter openings 117 respectively. Along the first direction A11, the second openings 108 cover the corresponding first openings 107 respectively, so the light emitted by the light-emitting elements 105 may be emitted through the corresponding color filters and have the color characteristics of the color filters.

In this embodiment, the third opening 109 of the light-blocking layer 106 is a structure that does not block light, and along the first direction A11, the first function device 201 overlaps the at least one third opening 109 in the first region 102. The transmittance of the third opening 109 at 940 nm is greater than 80%; infrared light emitted by the first function device 201 may be emitted through the at least one third opening 109, or external light (for example, the infrared light) may be incident on the first function device 201 through the at least one third opening 109; the first region 102 may fulfill the infrared light transmission function through the at least one third opening 109.

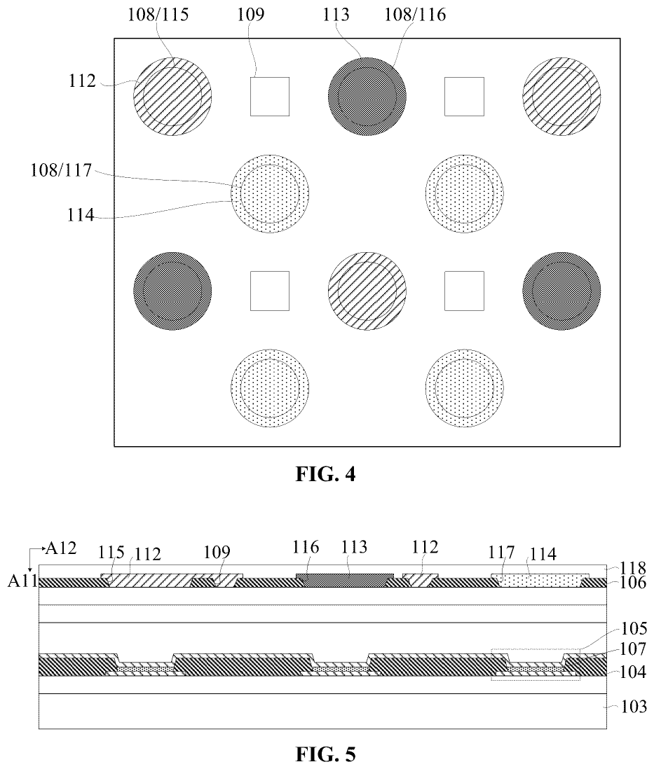

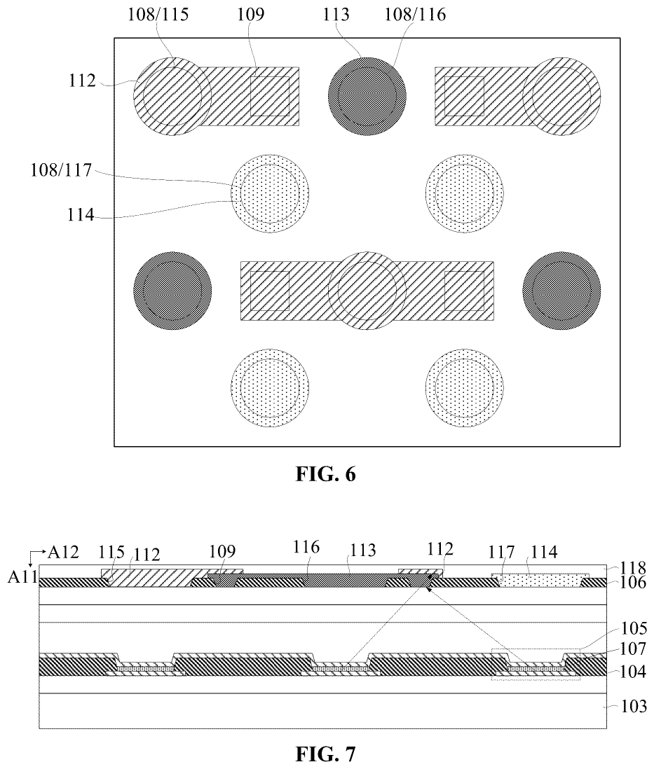

FIG. 5 is yet another diagram of a display panel according to an embodiment of the present disclosure. FIG. 6 is a partial top view of a first region in FIG. 5. As shown in FIGS. 5 and 6, optionally, the first color filter 112 is further located in the third opening 109. Any one of the second openings 108 or the third openings 109 shown in FIG. 6 is the lower opening thereof.

In this embodiment, the at least one third opening 109 is each filled with the first color filter 112. Optionally, the first color filter 112 is a red color filter. When the first color filter 112 fills the third opening 109, the third opening 109 can transmit the infrared light. In an embodiment, the third opening 109 has a high transmittance for the light of 940 nm. Adding the third opening 109 to the first region 102 can increase the infrared light transmittance and meet the infrared light transmittance requirements of the product. The third opening 109 filled with the first color filter 112 also has a blocking effect on visible light.

Optionally, the optical device disposed in the first region 102 include an infrared light distance sensor. Along the first direction A11, the infrared light distance sensor overlaps the at least one third opening 109 and at least one second opening 108. The opening region in the light-blocking layer 106 may allow the infrared light to pass through. The infrared light distance sensor senses the infrared light through an infrared light emission tube and an infrared light receiving tube therein to measure the distance from a display device to a target object (such as a face or finger) and then control a screen of the display device to turn on or off according to the distance.

In the first region 102, the third opening 109 is added, and the first color filter 112 is filled in the third opening 109, which can increase the infrared light transmittance of the first region 102 and allow the first region 102 to fulfill the infrared transmission function while ensuring the normal display of the first region 102, thereby being conducive to the fulfillment of the full screen.

It is to be noted that in the case where the third opening 109 is filled with the color filter, the third opening 109 in the first region 102 meets the requirements of transmitting the infrared light and blocking the visible light. Based on this, in subsequent embodiments, if the third opening 109 is filled with the color filter, light emission, light incidence, light transmission requirements, and transmittance of the first region 102 and/or the third opening 109 all refer to infrared light emission, infrared light incidence, infrared light transmission requirements, and infrared light transmittance.

In the display panel, the first region 102 includes multiple third openings 109, and the at least one third opening 109 is each filled with the first color filter 112, so the first region 102 can fulfill the infrared light transmission function, and the optical devices for sensing the infrared light may be disposed in the first region 102. Alternatively, in the display panel, some third openings 109 are not filled with color filters, and some third openings 109 are filled with first color filters 112, so the first region 102 may fulfill both the visible light transmission function and the infrared light transmission function; according to the requirements of the product, an optical device for sensing the visible light (such as a camera) and/or an optical device for sensing the infrared light (such as an infrared light distance sensor) may be disposed in the first region 102.

In this embodiment, if the third opening 109 is adjacent to the first color filter opening 115, the first color filter 112 may extend and simultaneously fill the third opening 109 and the first color filter opening 115. Alternatively, the same first color filter 112 may simultaneously fill at least one first color filter opening 115 and the at least one third opening 109. Alternatively, a first color filter 112 filled in the first color filter opening 115 and a first color filter 112 filled in the third opening 109 are independent of each other.

It is to be noted that the first region 102 has one or more third openings 109 newly dug only in the light-blocking layer 106, and the first color filters 112 fill the one or more third openings 109 so that the visible light transmittance of the one or more third openings 109 can be minimal, the increase in the reflectance (R %) of the corresponding first region 102 in the visible light range of 360 nm to 780 nm can be minimal, and the first region 102 cannot have a serious dark state visual effect, thereby ensuring a good display effect of the display panel.

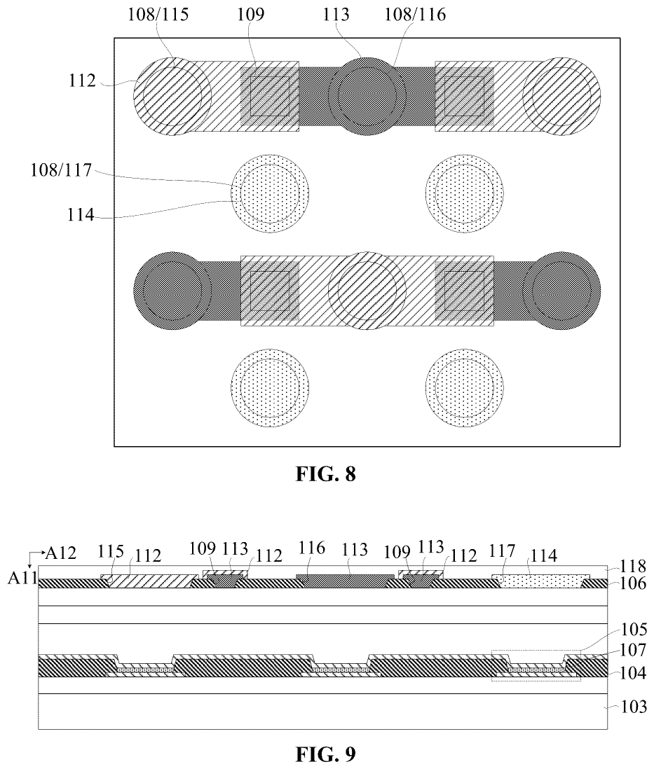

FIG. 7 is yet another diagram of a display panel according to an embodiment of the present disclosure. FIG. 8 is a partial top view of a first region in FIG. 7. As shown in FIGS. 7 and 8, optionally, the second color filter 113 is further located in the third opening 109; along the first direction A11, the first color filter 112 and the second color filter 113 overlap in the third opening 109. Any one of the second openings 108 or the third openings 109 shown in FIG. 8 is the lower opening thereof.

In this embodiment, the third opening 109 is filled with two color filters. In an embodiment, the third opening 109 is filled with the second color filter 113 and the first color filter 112 that are stacked. Optionally, the first color filter 112 is a red color filter, so the third opening 109 may be used as an opening for transmitting the infrared light. In the third opening 109, an overlapping region of the second color filter 113 and the first color filter 112 can reduce the characteristics of incidence and reflection of the external light, further block the visible light, increase the infrared light transmittance of the first region 102, and also allow the first region 102 to fulfill the infrared transmission function, thereby being conducive to the achievement of the full screen and increasing the optical detection accuracy of the optical devices of the first region 102. Optionally, in the third opening 109, the second color filter 113 is located between the first color filter 112 and the pixel definition layer 104. As shown in FIG. 7, the second color filter 113 is located between the first color filter 112 and the pixel definition layer 104. Under normal circumstances, most of light emitted by light-emitting elements 105 corresponding to the color filters is emitted through corresponding second openings 108, and large-angle light is blocked by the light-blocking layer 106.

In this embodiment, the third opening 109 is added to the light-blocking layer 106. Large-angle light emitted by a light-emitting element 105 corresponding to the second color filter 113 may be incident on an adjacent third opening 109, and the first color filter 112 located above the second color filter 113 in the third opening 109 may block the large-angle light to prevent the large-angle light emitted by the light-emitting element 105 corresponding to the second color filter 113 from being emitted and affecting the display effect and avoid problems such as light leakage and color cast on the display panel, thereby improving the display effect of the first region 102. Similarly, large-angle light emitted by a light-emitting element 105 corresponding to the third color filter 114 may be incident on an adjacent third opening 109, and the second color filter 113 and the first color filter 112 in the third opening 109 may block the large-angle light to prevent the large-angle light emitted by the light-emitting element 105 corresponding to the third color filter 114 from being emitted and affecting the display effect and avoid problems such as light leakage and color cast on the display panel, thereby improving the display effect of the first region 102.

As described in the preceding, if the third opening 109 is adjacent to the second color filter opening 116, the second color filter 113 may extend and simultaneously fill the third opening 109 and the second color filter opening 116. Alternatively, the same second color filter 113 may simultaneously fill at least one second color filter opening 116 and the at least one third opening 109. Alternatively, a second color filter 113 filled in the second color filter opening 116 and a second color filter 113 filled in the third opening 109 are independent of each other.

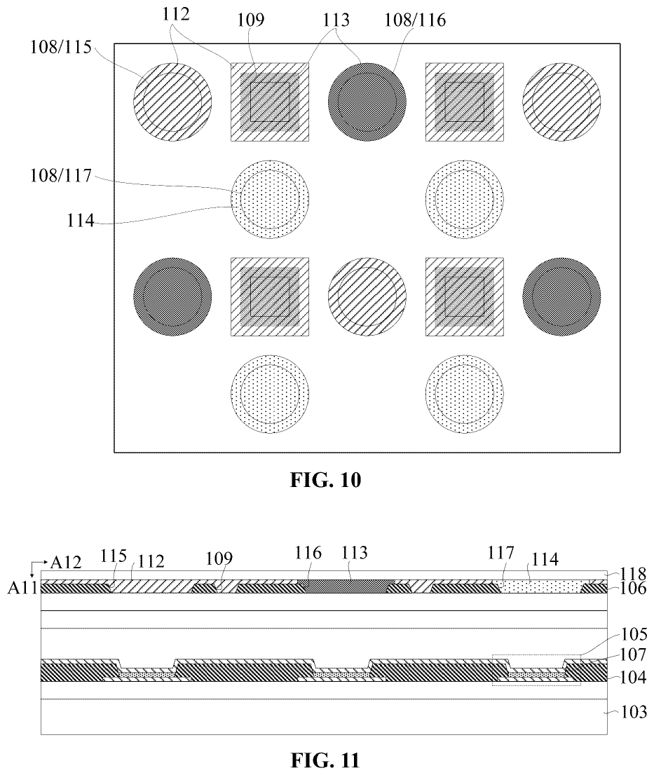

FIG. 9 is yet another diagram of a display panel according to an embodiment of the present disclosure. FIG. 10 is a partial top view of a first region in FIG. 9. As shown in FIGS. 9 and 10, optionally, for the third opening 109, along the first direction A11, the second color filter 113 covers the third opening 109, and the first color filter 112 covers the second color filter 113. Any one of the second openings 108 or the third openings 109 shown in FIG. 10 is the lower opening thereof.

In this embodiment, the at least one third opening 109 is each filled with the second color filter 113 and the first color filter 112 that are stacked. Optionally, the second color filter 113 filled in the third opening 109 is independent of the other second color filters 113, and along the first direction A11, the second color filter 113 covers the third opening 109, and the first color filter 112 covers the second color filter 113. In other words, the first color filter 112 completely covers the second color filter 113 in the third opening 109, and the second color filter 113 completely fills and covers the third opening 109. In this manner, on the basis of meeting the infrared transmission function of the third opening 109, the second color filter 113 and the first color filter 112 that completely cover the third opening 109 can prevent the large-angle light emitted by the light-emitting element 105 corresponding to the third color filter 114 from being emitted from the third opening 109, also prevent the large-angle light emitted by the light-emitting element 105 corresponding to the second color filter 113 from being emitted from the third opening 109, and also block the transmission of the visible light, thereby avoiding light leakage of the light-emitting elements 105 from the third opening 109.

As described in the preceding, the first color filter 112 in the third opening 109 and the first color filter 112 in the first color filter opening 115 may be independent of each other, and the second color filter 113 in the third opening 109 and the second color filter 113 in the second color filter opening 116 may be independent of each other. However, it is not limited to this.

It is to be noted that the first region 102 has one or more third openings 109 newly dug only in the light-blocking layer 106, and the stacked second color filter 113 and first color filter 112 fill the third opening 109. Therefore, the third opening 109 does not transmit the visible light basically. Compared with the second region 110, the increase (ΔR %) in the visible light reflectance of the first region 102 is minimal and may even be regarded as zero. Consequently, the first region 102 does not have a dark state visual effect so that a good display effect of the display panel can be ensured.

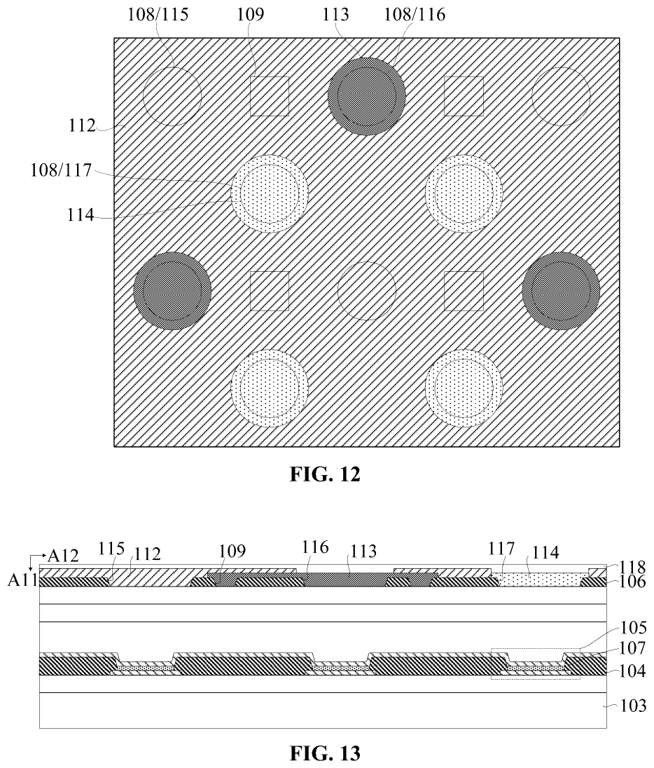

FIG. 11 is yet another diagram of a display panel according to an embodiment of the present disclosure. FIG. 12 is a partial top view of a first region in FIG. 11. As shown in FIGS. 11 and 12, optionally, along the first direction A11, the first color filter 112 covers at least one second opening 108 and the at least one third opening 109. Any one of the second openings 108 or the third openings 109 shown in FIG. 12 is the lower opening thereof.

In this embodiment, the multiple second openings 108 and the multiple third openings 109 are formed in the light-blocking layer 106. The second color filter openings 116 of the second openings 108 are filled with the second color filters 113 respectively, and the third color filter openings 117 of the second openings 108 are filled with the third color filters 114 respectively. Optionally, along the first direction A11, the second color filters 113 fill the second color filter openings 116 and extend to cover part of the light-blocking layer 106, and the third color filters 114 fill the third color filter openings 117 and extend to cover part of the light-blocking layer 106.

The first color filters 112 fill other light-blocking layer regions other than the second color filters 113 and the third color filters 114, so the first color filters 112 fill the multiple first color filter openings 115 and the multiple third openings 109 respectively. In this manner, the first region 102 may be used as an infrared light transmission region as a whole so that one or more infrared light sensors with the same or different functions can be integrated in the first region 102, thereby being conducive to the achievement of the full screen and fulfillment of the infrared light transmission function.

It is to be noted that the first region 102 has one or more third openings 109 newly dug only in the light-blocking layer 106, and the first color filters 112 fill the one or more third openings 109 and cover part or all of the light-blocking layer 106 so that the increase in the reflectance of the first region 102 in the visible light range of 360 nm to 780 nm can be minimal, and the first region 102 cannot have a dark state visual effect, thereby ensuring a good display effect of the display panel.

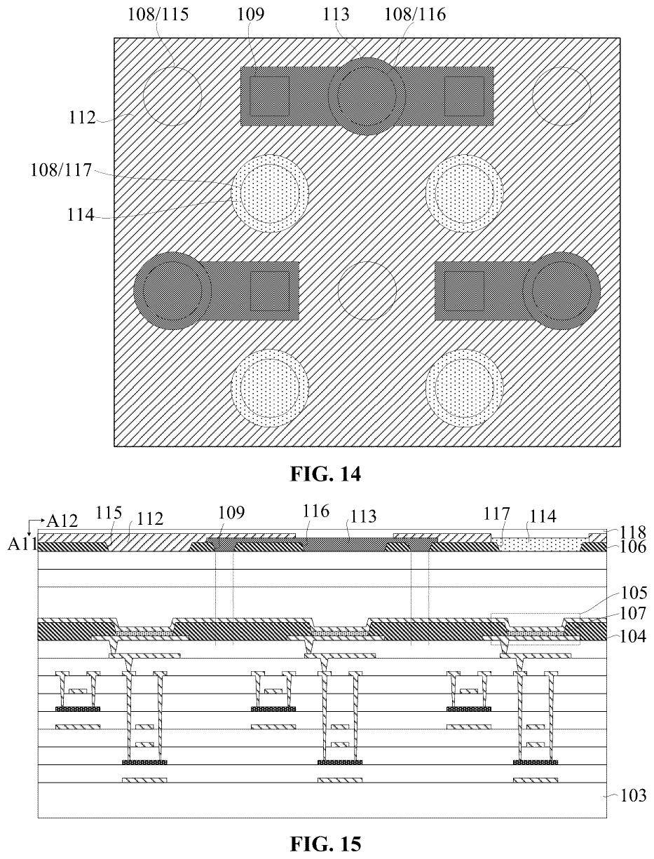

FIG. 13 is yet another diagram of a display panel according to an embodiment of the present disclosure. FIG. 14 is a partial top view of a first region in FIG. 13. As shown in FIGS. 13 and 14, optionally, the second color filter 113 located in the second color filter opening 116 extends to overlap the at least one third opening 109. Optionally, in the first region 102, the area of the orthographic projection of the light-blocking layer 106 along the first direction A11 is Sa, the area of the orthographic projection of the first color filter 112 along the first direction A11 is Sb, and Sb/Sa≥50%. Any one of the second openings 108 or the third openings 109 shown in FIG. 14 is the lower opening thereof.

In this embodiment, the multiple second openings 108 and the multiple third openings 109 are formed in the light-blocking layer 106. The second color filter openings 116 of the second openings 108 and the at least one third opening 109 are filled with the second color filters 113 respectively, and the third color filter openings 117 of the second openings 108 are filled with the third color filters 114 respectively. Optionally, along the first direction A11, the same second color filter 113 fills the second color filter opening 116 and extends to fill at least one adjacent third opening 109, and the third color filter 114 fills the third color filter opening 117 and extends to cover part of the light-blocking layer 106.

The same first color filter 112 fills multiple third openings 109 and multiple first color filter openings 115 in the light-blocking layer 106, so the first color filter 112 in the third opening 109 is stacked on the second color filter 113. In this manner, the first region 102 may be used as an infrared light transmission region as a whole so that one or more infrared light sensors with the same or different functions can be integrated in the first region 102, thereby being conducive to the achievement of the full screen and fulfillment of the infrared light transmission function. In addition, the first color filter 112 and the second color filter 113 that are stacked in the third opening 109 can effectively block the visible light.

It is to be noted that the first region 102 has one or more third openings 109 newly dug only in the light-blocking layer 106, and the stacked second color filter 113 and first color filter 112 fill the third opening 109. The first color filter 112 covers part or all of the light-blocking layer 106, so the first region 102 does not transmit the visible light basically. Compared with the second region 110, the increase in the visible light reflectance of the first region 102 is minimal and may even be regarded as zero. Consequently, the first region 102 does not have a dark state visual effect so that a good display effect of the display panel can be ensured.

Optionally, in the first region, the area of the orthographic projection of the light-blocking layer along the first direction is Sa, the area of the orthographic projection of the third opening along the first direction is Sc, and Sc/Sa≤10%. For any one of the preceding embodiments, optionally, Sc/Sa is greater than or equal to 3% and less than or equal to 10%. In the first region, if the area proportion of the third opening in the light-blocking layer is too large, the area proportion of the second opening in the light-blocking layer becomes small, thereby affecting the resolution of the first region. In the first region, if the area proportion of the third opening in the light-blocking layer is too small, it affects the infrared light transmittance of the first region, thereby affecting the operation performance of an infrared light sensor integrated in the first region, reducing the detection accuracy of the infrared light sensor, and affecting the infrared sensing effect of the display panel. Therefore, researchers and developers design that Sc/Sa≤10%. Optionally, 3%≤Sc/Sa≤10%. Certainly, depending on different fields to which the display panel is applied, the relevant practitioners may reasonably design the ratio of Sc/Sa according to the requirements of the product without specific restrictions.

Optionally, along the first direction, the color filter film thickness of any one of the second openings 108 or the third openings 109 is greater than or equal to 2.5 μm and less than or equal to 4 μm. During the manufacturing process of the display panel, a high-transmittance CF (color filter) technique or a low-transmittance CF technique may be selected according to the application requirements of the product. Herein, CF refers to a color filter in this embodiment. The film thickness of the color filter refers to the thickness size of the color filter in an opening along the first direction.

In this embodiment, when the high-transmittance CF technique is selected based on the application requirements of the product, the film thickness of the color filter in the second opening 108 may be designed to be greater than or equal to 2.5 μm and less than or equal to 4 μm. In an embodiment, the second openings 108 include the first color filter openings 115 filled with the first color filters 112, the second color filter openings 116 filled with the second color filters 113, and the third color filter openings 117 filled with the third color filters 114. The color filter film thickness of any color filter opening is greater than or equal to 2.5 μm and less than or equal to 4 μm. Exemplarily, optionally, the first color filter 112 is a red color filter, the second color filter 113 is a blue color filter, and the third color filter 114 is a green color filter. It is detected that the transmittance of the red color filter in the first color filter opening 115 ranges from 67% to 78%, the transmittance of the blue color filter in the second color filter opening 116 ranges from 71% to 80%, and the transmittance of the green color filter in the third color filter opening 117 ranges from 55% to 69%.

In an embodiment, the film thickness of the red color filter is designed to range from 2.5 μm to 4 μm. It is detected that the transmittance of the red color filter with the film thickness of 2.5 μm is about 78%. As the film thickness of the red color filter gradually increases to 4 μm, the transmittance of the red color filter decreases to 67%. Similarly, the film thickness of the blue color filter is designed to range from 2.5 μm to 4 μm. It is detected that the transmittance of the blue color filter with the film thickness of 2.5 μm is about 80%. As the film thickness of the blue color filter gradually increases to 4 μm, the transmittance of the blue color filter decreases to 71%. Similarly, the film thickness of the green color filter is designed to range from 2.5 μm to 4 μm. It is detected that the transmittance of the green color filter with the film thickness of 2.5 μm is about 69%. As the film thickness of the green color filter gradually increases to 4 μm, the transmittance of the green color filter decreases to 55%. Therefore, for a single-colored color filter, the smaller the film thickness, the larger the transmittance; the larger the film thickness, the smaller the transmittance.

When the high-transmittance CF technique is selected based on the application requirements of the product, the film thickness of the color filter in the third opening 109 may be designed to be greater than or equal to 2.5 μm and less than or equal to 4 μm. In an embodiment, if the third opening 109 only includes the first color filter 112, the film thickness of the first color filter 112 is greater than or equal to 2.5 μm and less than or equal to 4 μm. If the third opening 109 includes the first color filter 112 and the second color filter 113 that are stacked, along the first direction, the sum of the film thicknesses of the first color filter 112 and the second color filter 113 in the third opening 109 is greater than or equal to 2.5 μm and less than or equal to 4 μm.

Optionally, in the third opening 109, the film thickness of the first color filter 112 is different from the film thickness of the second color filter 113. Optionally, in the third opening 109, the film thickness of the first color filter 112 is smaller than the film thickness of the second color filter 113. Optionally, in the third opening 109, the film thickness of the first color filter 112 is greater than or equal to 0.7 μm and less than or equal to 2 μm. Optionally, in the third opening 109, the film thickness of the second color filter 113 is greater than or equal to 2 μm and less than or equal to 3 μm.

As described in the preceding, for a single-colored color filter, of the same film thickness (such as 2.5 μm), the transmittance of the green color filter (69%), the transmittance of the red color filter (78%), and the transmittance of the blue color filter (80%) are arranged in an ascending order. Similarly, for a single-colored color filter, of the same transmittance (such as 78%), the film thickness of the green color filter (less than 2.5 μm), the film thickness of the red color filter (equal to 2.5 μm), and the film thickness of the blue color filter (greater than 2.5 μm) are arranged in an ascending order. Optionally, the first color filter 112 is a red color filter, and the second color filter 113 is a blue color filter. In the case where the third opening 109 includes the first color filter 112 and the second color filter 113 that are stacked, optionally, the film thickness of the first color filter 112 is smaller than the film thickness of the second color filter 113. In this manner, the difference between the transmittance of the first color filter 112 and the transmittance of the second color filter 113 in the third opening 109 can be reduced. Moreover, the film thickness of the first color filter 112 and the film thickness of the second color filter 113 can be even reasonably designed so that the difference between the transmittance of the first color filter 112 and the transmittance of the second color filter 113 in the third opening 109 can be eliminated or kept within an allowable range.

In addition, the film thickness of any one of the first color filters 112, the second color filters 113, or the third color filters 114 in the second openings 108 is designed to be greater than or equal to 2.5 μm and less than or equal to 4 μm. It is detected that for a region in which the second opening 108 is located, the color rendering index Re is 6.62, the hue value a* is about −1.51, and the hue value b* is about −0.99. Using the values of the region in which the second opening 108 is located as the base, the difference of the reflectance hue-related value of a region in which the third opening 109 is located relative to the base is within the range of ±0.2. Therefore, a human eye neither recognizes the difference between the third opening 109 and the second opening 108 nor recognizes the display difference between the second region 110 and the first region 102, which indicates a good display effect of the display panel.

Based on this, by repeatedly adjusting the film thickness of the first color filter 112 and the film thickness of the second color filter 113 in the third opening 109, in the case where the third opening 109 includes the first color filter 112 and the second color filter 113 that are stacked, optionally, the film thickness of the first color filter 112 in the third opening 109 is greater than or equal to 0.7 μm and less than or equal to 2 μm, and the film thickness of the second color filter 113 in the third opening 109 is greater than or equal to 2 μm and less than or equal to 3 μm.

Exemplarily, in the case where the third opening 109 includes the first color filter 112 and the second color filter 113 that are stacked, optionally, in the third opening 109, the film thickness of the first color filter 112 is 0.7 μm, and the film thickness of the second color filter 113 is 2 μm; in this manner, it is detected that for the region in which the third opening 109 is located, the color rendering index Re is 6.63, the hue value a* is about −1.45, and the hue value b* is about −1.20. Alternatively, optionally, in the third opening 109, the film thickness of the first color filter 112 is 1.5 μm, and the film thickness of the second color filter 113 is 3 μm; in this manner, it is detected that for the region in which the third opening 109 is located, the color rendering index Re is 6.62, the hue value a* is about −1.51, and the hue value b* is about −1.01. Alternatively, optionally, in the third opening 109, the film thickness of the first color filter 112 is 1 μm, and the film thickness of the second color filter 113 is 2 μm; in this manner, it is detected that for the region in which the third opening 109 is located, the color rendering index Re is 6.62, the hue value a* is about −1.49, and the hue value b* is about −1.08.

It is detected that if the film thickness of the first color filter 112 in the third opening 109 is less than 0.7 μm, and/or the film thickness of the second color filter 113 in the third opening 109 is less than 2 μm, the difference between the hue value b* and the base exceeds the range of ±0.2. If the film thickness of the first color filter 112 in the third opening 109 is greater than 2 μm, and/or the film thickness of the second color filter 113 in the third opening 109 is greater than 3 μm, the thickness of the color filters in the third opening 109 is too large, which affects the thinning, and the difference between at least one of the hue value a* or the hue value b* and the base may also exceed the range of ±0.2.

Optionally, along the first direction, the color filter film thickness of any one of the second openings 108 or the third openings 109 is greater than or equal to 2.5 μm and less than or equal to 3.5 μm.

In this embodiment, when the low-transmittance CF technique is selected based on the application requirements of the product, the film thickness of the color filter in the second opening 108 may be designed to be greater than or equal to 2.5 μm and less than or equal to 3.5 μm, and the film thickness of the color filter in the third opening 109 may be designed to be greater than or equal to 2.5 μm and less than or equal to 3.5 μm. In the case where the third opening 109 includes a single first color filter 112, the film thickness of the first color filter 112 is designed to be greater than or equal to 2.5 μm and less than or equal to 3.5 μm. In the case where the third opening 109 includes the first color filter 112 and the second color filter 113 that are stacked, the sum of the film thicknesses of the first color filter 112 and the second color filter 113 in the third opening 109 is greater than or equal to 2.5 μm and less than or equal to 3.5 μm.

For a single-colored color filter, when the film thickness is greater than or equal to 2.5 μm and less than or equal to 3.5 μm, it is detected that the transmittance of the red color filter ranges from 52% to 63%, the transmittance of the blue color filter ranges from 57% to 67%, and the transmittance of the green color filter ranges from 42% to 52%. For the single-colored color filter, the smaller the film thickness, the larger the transmittance; the larger the film thickness, the smaller the transmittance.

Optionally, in the third opening 109, the film thickness of the first color filter 112 is different from the film thickness of the second color filter 113. Optionally, in the third opening 109, the film thickness of the first color filter 112 is smaller than the film thickness of the second color filter 113. Optionally, in the third opening 109, the film thickness of the first color filter 112 is greater than or equal to 1 μm and less than or equal to 2 μm. Optionally, in the third opening 109, the film thickness of the second color filter 113 is greater than or equal to 1 μm and less than or equal to 3 μm. Exemplarily, optionally, the first color filter 112 is a red color filter, and the second color filter 113 is a blue color filter.

In this embodiment, in the case where the third opening 109 includes the first color filter 112 and the second color filter 113 that are stacked, optionally, the film thickness of the first color filter 112 is smaller than the film thickness of the second color filter 113. In this manner, the difference between the transmittance of the first color filter 112 and the transmittance of the second color filter 113 in the third opening 109 can be reduced. Moreover, the film thickness of the first color filter 112 and the film thickness of the second color filter 113 can be even reasonably designed so that the difference between the transmittance of the first color filter 112 and the transmittance of the second color filter 113 in the third opening 109 can be eliminated or kept within an allowable range.

In addition, the film thickness of any one of the first color filters 112, the second color filters 113, or the third color filters 114 in the second openings 108 is designed to be greater than or equal to 2.5 μm and less than or equal to 3.5 μm. It is detected that for the region in which the second opening 108 is located, the color rendering index Re is 5.42, the hue value a* is about −0.07, and the hue value b* is about −1.11. Using the values of the region in which the second opening 108 is located as the base, the difference of the reflectance hue-related value of the region in which the third opening 109 is located relative to the base is within the range of ±0.2. Therefore, the human eye neither recognizes the difference between the third opening 109 and the second opening 108 nor recognizes the display difference between the second region 110 and the first region 102, which indicates a good display effect of the display panel.

Based on this, by repeatedly adjusting the film thickness of the first color filter 112 and the film thickness of the second color filter 113 in the third opening 109, in the case where the third opening 109 includes the first color filter 112 and the second color filter 113 that are stacked, optionally, the film thickness of the first color filter 112 in the third opening 109 is greater than or equal to 1 μm and less than or equal to 2 μm, and the film thickness of the second color filter 113 in the third opening 109 is greater than or equal to 1 μm and less than or equal to 3 μm.

Exemplarily, in the case where the third opening 109 includes the first color filter 112 and the second color filter 113 that are stacked, optionally, in the third opening 109, the film thickness of the first color filter 112 is 1 μm, and the film thickness of the second color filter 113 is 1 μm; in this manner, it is detected that for the region in which the third opening 109 is located, the color rendering index Re is 5.43, the hue value a* is about 0.00, and the hue value b* is about −1.25. Alternatively, optionally, in the third opening 109, the film thickness of the first color filter 112 is 2 μm, and the film thickness of the second color filter 113 is 2 μm; in this manner, it is detected that for the region in which the third opening 109 is located, the color rendering index Re is 5.42, the hue value a* is about −0.07, and the hue value b* is about −1.12. Alternatively, optionally, in the third opening 109, the film thickness of the first color filter 112 is 1.5 μm, and the film thickness of the second color filter 113 is 3 μm; in this manner, it is detected that for the region in which the third opening 109 is located, the color rendering index Re is 5.42, the hue value a* is about −0.07, and the hue value b* is about −1.14.

It is detected that if the film thickness of the first color filter 112 in the third opening 109 is less than 1 μm, and/or the film thickness of the second color filter 113 in the third opening 109 is less than 1 μm, the difference between at least one of the hue value a* or the hue value b* and the base exceeds the range of ±0.2. If the film thickness of the first color filter 112 in the third opening 109 is greater than 2 μm, and/or the film thickness of the second color filter 113 in the third opening 109 is greater than 3 μm, the thickness of the color filters in the third opening 109 is too large, which affects the thinning, and the difference between at least one of the hue value a* or the hue value b* and the base may also exceed the range of ±0.2.

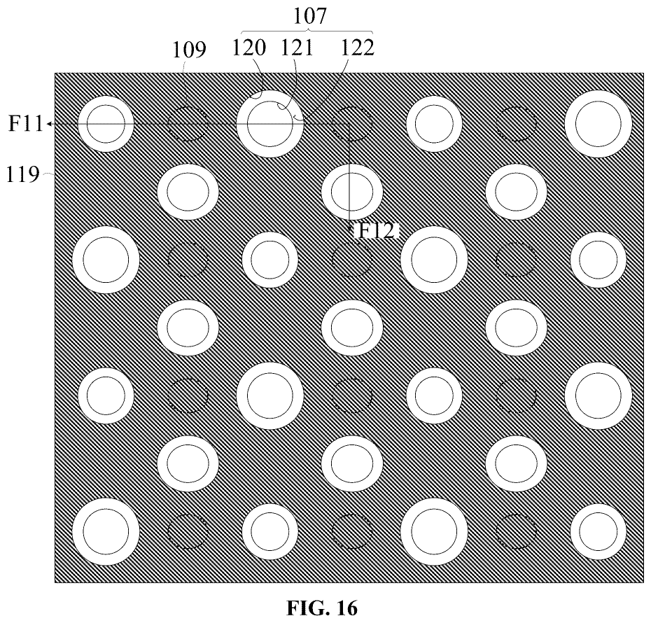

FIG. 15 is yet another diagram of a display panel according to an embodiment of the present disclosure. FIG. 16 is a partial top view of a pixel definition layer in FIG. 15. As shown in FIGS. 15 and 16, optionally, the pixel definition layer 104 includes a first non-opening region 119; along the first direction A11, the orthographic projection of the third opening 109 is located in the first non-opening region 119. The cross-sectional structure of the pixel definition layer 104 along F11-F12 in FIG. 16 may be referred to as the pixel definition layer 104 shown in FIG. 15. The third openings 109 shown in FIG. 16 are substantially the orthographic projections of the third openings 109 on the pixel definition layer 104. Exemplarily, optionally, the first openings 107 and the third openings 109 are all circular, which is not limited to this, and the relevant practitioners may reasonably design the shapes of the first openings, the second openings, and the third openings according to the requirements of the product.

In this embodiment, the pixel definition layer 104 includes the multiple first openings 107. In an embodiment, the first opening 107 includes the upper opening 120, the lower opening 121, and the inner sidewall 122 connected between the upper opening 120 and the lower opening 121. A region surrounded by the lower opening 121 is substantially a light-emitting region of a corresponding light-emitting element 105. A pixel definition layer region other than the regions surrounded by the upper openings 120 in the pixel definition layer 104 is a non-opening region of the pixel definition layer 104, and the first non-opening region 119 is part or all of the non-opening region of the pixel definition layer 104.

Along the first direction A11, the orthographic projection of the third opening 109 is located in the first non-opening region 119 and does not overlap the upper opening 120 of the first opening 107. In other words, along the first direction A11, a pixel definition layer region corresponding to the orthographic projection of the third opening 109 does not have an opening, so the third opening 109 does not affect the light-emitting region of the light-emitting element 105, thereby ensuring the normal display function of the display panel. Moreover, at least the first color filter 112 fills the third opening 109, and the first color filter 112 covers part or all of the light-blocking layer 106, so the first region 102 does not transmit the visible light basically so that the first region 102 can meet the infrared light transmission requirements; the first region 102 does not have an increase in the reflectance relative to other regions and does not have a dark state visual effect so that a good display effect of the display panel can be ensured.

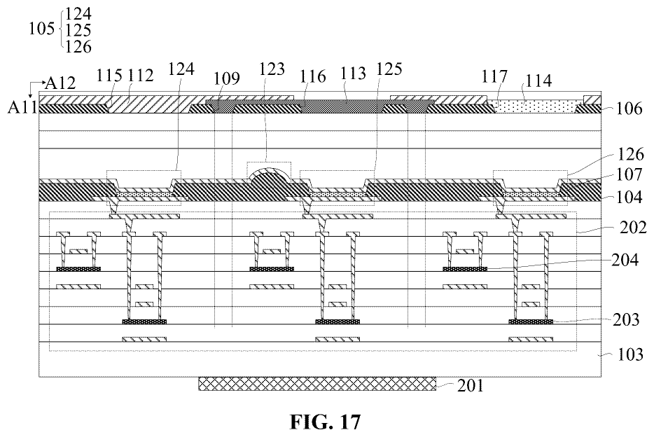

FIG. 17 is yet another diagram of a display panel according to an embodiment of the present disclosure. As shown in FIG. 17, optionally, the pixel definition layer 104 includes multiple first spacer portions 123; along the first direction A11, the third opening 109 does not overlap a first spacer portion 123. Optionally, along the first direction A11, the first spacer portion 123 overlaps the first non-opening region.

In this embodiment, the non-opening region of the pixel definition layer 104 is provided with one or more first spacer portions 123, and the one or more first spacer portions 123 are configured to support the display panel in the first direction A11; when the display panel is an organic light-emitting display panel, the one or more first spacer portions 123 may also support a mask during the evaporation process. The projection of the structure of a first spacer portion 123 in the first direction A11 may be an ellipse, a circle, or a rounded rectangle, which is not limited to this.

Along the first direction A11, the orthographic projection of the third opening 109 is located in the first non-opening region 119, the first spacer portion 123 is located in the non-opening region of the pixel definition layer 104, and the third opening 109 does not overlap the first spacer portion 123. If the first non-opening region 119 is part of the non-opening region of the pixel definition layer 104, the first spacer portion 123 may be located within the first non-opening region 119 along the first direction A11, or the first spacer portion 123 may partially overlap the first non-opening region 119 along the first direction A11, or the first spacer portion 123 may be located outside the first non-opening region 119 along the first direction A11. If the first non-opening region 119 is the entire non-opening region of the pixel definition layer 104, the first spacer portion 123 is located within the first non-opening region 119 along the first direction A11.

The relevant practitioners may reasonably design the distribution positions and distribution density of the first spacer portions 123 in the non-opening region of the pixel definition layer 104 according to the requirements of the product, which are not specifically limited in the present disclosure. Exemplarily, using the current mobile phone of the conventional size as an example, the non-opening region of the pixel definition layer 104 of the display panel in the mobile phone is provided with the first spacer portions 123; the first spacer portion 123 along the first direction A11 may be in the shape of a square, and the size of the square may be 8.5 μm*8.5 μm.

As shown in FIG. 17, optionally, the display region further includes an active layer located between the substrate 103 and the light-blocking layer 106; along the first direction A11, the third opening 109 does not overlap the active layer.

In this embodiment, the display panel may be the organic light-emitting display panel. However, it is not limited to this.

The display panel includes the substrate 103 on which a thin-film transistor array layer 202 is disposed. The thin-film transistor array layer 202 includes multiple thin-film transistors. As part of a pixel circuit structure, the thin-film transistor array layer 202 is configured to drive the light-emitting elements 105 to display.

The thin-film transistor array layer 202 includes a first active layer 203. Optionally, the first active layer 203 is a polysilicon (poly) layer, in an embodiment, a low-temperature polycrystalline silicon (LTPS) layer. Along the first direction A11, the third opening 109 does not overlap the first active layer 203, so light emitted by the first function device 201 is not blocked by the first active layer 203 so that the light emitted by the first function device 201 can be emitted through the third opening 109; or the external light is not blocked by the first active layer 203 after passing through the third opening 109 so that the external light can be incident on the first function device 201 through the third opening 109.

At present, the thin-film transistor array layer 202 in part of the organic light-emitting display panel further includes a second active layer 204. Optionally, the second active layer 204 is a metal oxide layer, in an embodiment, an indium gallium zinc oxide (IGZO) layer. Optionally, the second active layer 204 is located between the first active layer 203 and the pixel definition layer 104. Similarly, along the first direction A11, the third opening 109 also does not overlap the second active layer 204, so the light emitted by the first function device 201 is not blocked by the second active layer 204; or the external light is not blocked by the second active layer 204 after passing through the third opening 109, so it is beneficial for the first function device 201 to receive and send light through the third opening 109.

It is to be noted that along the first direction A11, the third opening 109 does not overlap the active layers, thereby ensuring the infrared light transmission requirements of the first region 102, so that the first function device 201 can operate normally.

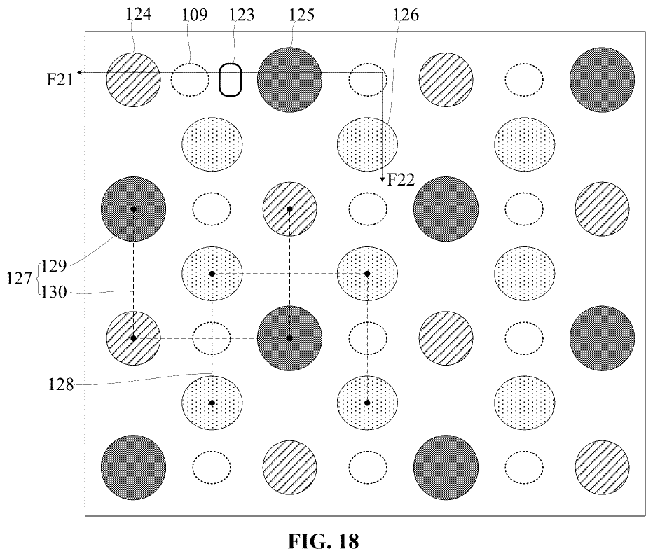

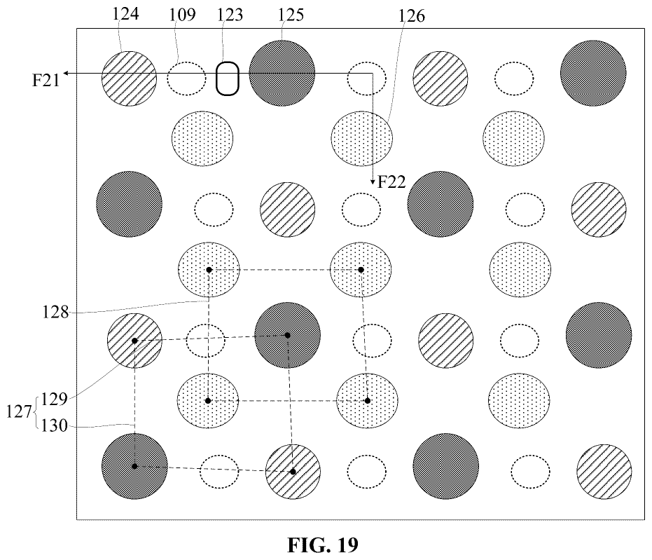

FIG. 18 is a partial top view of a pixel definition layer in FIG. 17. FIG. 19 is another partial top view of a pixel definition layer in FIG. 17. As shown in FIGS. 17 to 19, optionally, the multiple light-emitting elements 105 include first color light-emitting elements 124, second color light-emitting elements 125, and third color light-emitting elements 126. Two first color light-emitting elements 124 and two second color light-emitting elements 125 form a first virtual quadrilateral 127. The two first color light-emitting elements 124 are located at first vertexes of the first virtual quadrilateral 127 respectively, and the two second color light-emitting elements 125 are located at second vertexes of the first virtual quadrilateral 127 respectively. The first vertexes and the second vertexes in the first virtual quadrilateral 127 are alternately spaced apart, and a third color light-emitting element 126 is located within the first virtual quadrilateral 127. Moreover, four third color light-emitting elements 126 form a second virtual quadrilateral 128. The four third color light-emitting elements 126 are located at vertexes of the second virtual quadrilateral 128 respectively. A first color light-emitting element 124 or a second color light-emitting element 125 is located within the second virtual quadrilateral 128.

The cross-sectional structure of the pixel definition layer 104 along F21-F22 in FIGS. 18 and 19 may be referred to as the pixel definition layer 104 shown in FIG. 17. The third openings 109 shown in FIGS. 18 and 19 are substantially the orthographic projections of the third openings 109 on the pixel definition layer 104. The light-emitting elements 105 shown in FIGS. 18 and 19 have the shapes of the light-emitting regions of the light-emitting elements 105, that is, the shapes of the lower openings of the first openings 107. Exemplarily, optionally, the first openings 107 and the third openings 109 are all circular, which is not limited to this.

For the first virtual quadrilateral 127, the shape may be a regular quadrilateral such as a square, a rectangle, or a parallelogram, or may also be an irregular quadrilateral. Exemplarily, the first virtual quadrilateral 127 formed by the two first color light-emitting elements 124 and the two second color light-emitting elements 125 in FIG. 18 is in the shape of a rectangle. The first virtual quadrilateral 127 formed by the two first color light-emitting elements 124 and the two second color light-emitting elements 125 in FIG. 19 is in the shape of an irregular quadrilateral. However, it is not limited to this. In other embodiments, according to the layout of the first openings 107 in the pixel definition layer 104, the shape of the first virtual quadrilateral 127 changes accordingly.

For the second virtual quadrilateral 128, the shape may be a regular quadrilateral or an irregular quadrilateral. Exemplarily, the second virtual quadrilateral 128 formed by the four third color light-emitting elements 126 in FIG. 18 is in the shape of a rectangle. The second virtual quadrilateral 128 formed by the four third color light-emitting elements 126 in FIG. 19 is in the shape of an irregular quadrilateral. However, it is not limited to this. In other embodiments, according to the layout of the first openings 107 in the pixel definition layer 104, the shape of the second virtual quadrilateral 128 changes accordingly.

In this embodiment, optionally, the light-emitting regions of the light-emitting elements 105 (that is, the lower openings of the first openings 107) are all in the shape of a circle. However, it is not limited to this. In other embodiments, the lower opening of the first opening may also be in the shape of an irregular quadrilateral, a regular quadrilateral, an ellipse, a rounded rectangle, or others.

As shown in FIG. 17, along the first direction A11, a first color light-emitting element 124 overlaps a first color filter 112 in a first color filter opening 115, a second color light-emitting element 125 overlaps a second color filter 113 in a second color filter opening 116, and a third color light-emitting element 126 overlaps a third color filter 114 in a third color filter opening 117. After light emitted by the first color light-emitting element 124 passes through the first color filter 112, the emitted light is configured as red light; after light emitted by the second color light-emitting element 125 passes through the second color filter 113, the emitted light is configured as blue light; after light emitted by the third color light-emitting element 126 passes through the third color filter 114, the emitted light is configured as green light. Accordingly, the first color light-emitting element 124 may be a red light-emitting element, the second color light-emitting element 125 may be a blue light-emitting element, and the third color light-emitting element 126 may be a green light-emitting element. However, it is not limited to this. The relevant practitioners may reasonably configure the colors of the first color light-emitting element, the second color light-emitting element, and the third color light-emitting element according to the requirements of the product. The colors of the first color light-emitting element, the second color light-emitting element, and the third color light-emitting element may be the same, may not be completely the same, may be completely different, and the like.

As shown in FIG. 18 or 19, optionally, the orthographic projection of the third opening 109 along the first direction A11 is located between adjacent first color light-emitting element 124 and second color light-emitting element 125.

In this embodiment, the distance from a non-opening region of the first color light-emitting element 124 to a non-opening region of the second color light-emitting element 125 is large. The distance from the non-opening region of the first color light-emitting element 124 to a non-opening region of the third color light-emitting element 126 is small. The distance from the non-opening region of the second color light-emitting element 125 to the non-opening region of the third color light-emitting element 126 is small.

It can be seen that the gap between the first color filter opening 115 corresponding to the first color light-emitting element 124 and the second color filter opening 116 corresponding to the second color light-emitting element 125 is large, so there is enough space to dispose the third opening 109, and the third opening 109 can also be allowed to keep a sufficient distance from the first color filter opening 115, the second color filter opening 116, and the third color filter opening 117. Accordingly, along the first direction A11, the orthographic projection of the third opening 109 is located between the adjacent first color light-emitting element 124 and second color light-emitting element 125 and can keep a sufficient distance from the adjacent first color light-emitting element 124 and second color light-emitting element 125, thereby reducing the risk of emitting light emitted by the light-emitting elements 105 through the third opening 109.

As shown in FIG. 18 or 19, optionally, the first virtual quadrilateral 127 includes a first virtual side 129 and a second virtual side 130 that are connected to each other; the orthographic projection of the third opening 109 along the first direction A11 is located between a first color light-emitting element 124 and a second color light-emitting element 125 that are connected to the first virtual side 129.

In this embodiment, the first virtual quadrilateral 127 includes four virtual sides connected sequentially, and two of the connected virtual sides are defined as the first virtual side 129 and the second virtual side 130. In FIG. 18, the first virtual quadrilateral 127 is in the shape of a rectangle, so the first virtual side 129 and the second virtual side 130 that are connected to each other in the first virtual quadrilateral 127 intersect perpendicularly. In FIG. 19, the first virtual quadrilateral 127 is in the shape of an irregular quadrilateral, so the first virtual side 129 and the second virtual side 130 that are connected to each other in the first virtual quadrilateral 127 intersect.

The display panel includes the multiple light-emitting elements 105. Multiple first color light-emitting elements 124 and multiple second color light-emitting elements 125 are alternately arranged along the extension direction of the first virtual side 129 to form one row of light-emitting elements 105, and multiple rows of light-emitting elements 105 are sequentially arranged along the extension direction of the second virtual side 130. Multiple first color light-emitting elements 124 and multiple second color light-emitting elements 125 are alternately arranged along the extension direction of the second virtual side 130 to form one column of light-emitting elements 105, and multiple columns of light-emitting elements 105 are sequentially arranged along the extension direction of the first virtual side 129.

Along the first direction A11, the orthographic projection of the third opening 109 is located between the first color light-emitting element 124 and the second color light-emitting element 125 that are connected to the first virtual side 129. In an embodiment, along the first direction A11, the orthographic projection of the third opening 109 overlaps the first virtual side 129; or along the first direction A11, the orthographic projection of the third opening 109 is located on a side of the first virtual side 129.

Optionally, the pixel definition layer 104 includes the multiple first spacer portions 123; the first spacer portion 123 is located between adjacent first color light-emitting element 124 and second color light-emitting element 125.

In this embodiment, the distance from a non-opening region of the first color light-emitting element 124 to a non-opening region of the second color light-emitting element 125 is large, so there is enough space to dispose the first spacer portion 123, and the first spacer portion 123 can be also allowed to keep a sufficient distance from the first color light-emitting element 124, the second color light-emitting element 125, and the third color light-emitting element 126.

As shown in FIG. 18 or 19, two adjacent first color light-emitting element 124 and second color light-emitting element 125 are present, and a third opening 109 and a first spacer portion 123 may be disposed between the two adjacent first color light-emitting element 124 and second color light-emitting element 125.

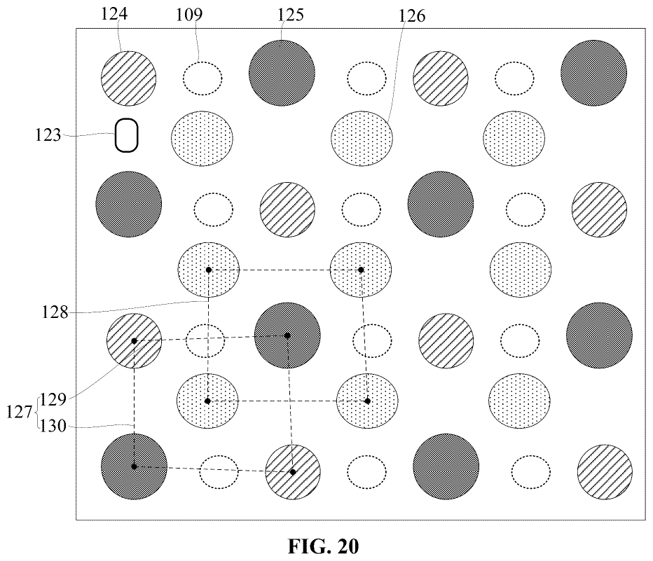

FIG. 20 is yet another partial top view of a pixel definition layer in FIG. 17. As shown in FIG. 20, optionally, the first virtual quadrilateral 127 includes the first virtual side 129 and the second virtual side 130 that are connected to each other; in the first region 102, the first spacer portion 123 is located between a first color light-emitting element 124 and a second color light-emitting element 125 that are connected to the second virtual side 130.

In this embodiment, the distance from a non-opening region of the first color light-emitting element 124 to a non-opening region of the second color light-emitting element 125 is large.

Optionally, a third opening 109 is disposed between the adjacent first color light-emitting element 124 and second color light-emitting element 125, or a first spacer portion 123 is disposed between the adjacent first color light-emitting element 124 and second color light-emitting element 125. In other words, the third opening 109 and the first spacer portion 123 are not disposed simultaneously between the adjacent first color light-emitting element 124 and second color light-emitting element 125. In an embodiment, optionally, the third opening 109 may be disposed between the adjacent first color light-emitting element 124 and second color light-emitting element 125 along the extension direction of the first virtual side 129; and the first spacer portion 123 may be disposed between the adjacent first color light-emitting element 124 and second color light-emitting element 125 along the extension direction of the second virtual side 130. Optionally, along the first direction A11, the first spacer portion 123 overlaps the second virtual side 130; or along the first direction A11, the first spacer portion 123 is located on a side of the second virtual side 130.

Based on this, the first spacer portion 123 can be allowed to keep a sufficient distance from the first color light-emitting element 124, the second color light-emitting element 125, and the third color light-emitting element 126, and the orthographic projection of the third opening 109 is allowed to keep a sufficient distance from the adjacent first color light-emitting element 124 and second color light-emitting element 125.

The first spacer portion 123 can support the mask during the manufacturing process of the mask. If located too close to the first opening 107, the first spacer portion 123 is squeezed by the mask and other tools during the manufacturing process of the mask and may easily fall into the first opening 107, forming a display dark spot and affecting the yield. In particular, at present, the display panel pursues a high value of pixels per inch (PPI), and to ensure the density of the first spacer portions 123, the size of the first spacer portion 123 cannot be compressed to the limit, resulting in a low yield of the panel. In this embodiment, if the first spacer portion 123 is disposed between the adjacent first color light-emitting element 124 and second color light-emitting element 125, the third opening 109 is not disposed simultaneously so that there can be enough space to dispose the first spacer portion 123, and the position of the first spacer portion 123 can be controlled to be away from the first opening 107. In this manner, while the density of the first spacer portions 123 is ensured, the risk of the first spacer portion 123 falling into the first opening 107 can be reduced, thereby improving the manufacturing yield and the display effect, and the size of the first spacer portion 123 can also be increased to a certain extent, thereby ensuring the support effect.

As shown in FIG. 20, optionally, along the direction of the first virtual side 129, the size of the third opening 109 is greater than or equal to the size of the first spacer portion 123; along the direction of the second virtual side 130, the size of the third opening 109 is greater than or equal to the size of the first spacer portion 123.

When the display panel pursues a high value of the PPI, the distance between adjacent first openings 107 is small. If the size of the first spacer portion 123 is too large, the first spacer portion 123 is located close to the first opening 107, thereby increasing the risk of the first spacer portion 123 falling into the first opening 107. In this embodiment, the size of the first spacer portion 123 is designed to be small. Under the same value of the PPI, the distance from the position of the first spacer portion 123 to the first opening 107 is increased, thereby reducing the risk of the first spacer portion 123 falling into the first opening 107 and improving the yield of the display panel.

The at least one third opening 109 is added to the light-blocking layer 106 to increase the transmittance of the first region 102. If the size of the third opening 109 is too small, it is not conducive to the transmittance of the first region 102. In this embodiment, the size of the third opening 109 is designed to be large, which can increase the transmittance of the first region 102.

In this embodiment, the non-opening region space between the adjacent first color light-emitting element 124 and second color light-emitting element 125 along the extension direction of the first virtual side 129 is approximately equal to the non-opening region space between the adjacent first color light-emitting element 124 and second color light-emitting element 125 along the extension direction of the second virtual side 130. In other words, the space for disposing the third opening 109 between the adjacent first color light-emitting element 124 and second color light-emitting element 125 is approximately equal to the space for disposing the first spacer portion 123 between the adjacent first color light-emitting element 124 and second color light-emitting element 125. If the size of the first spacer portion 123 is smaller than the size of the third opening 109 in the same direction, the size of the first spacer portion 123 is smaller, which is conducive to the increase in the distance from the position of the first spacer portion 123 to the first opening 107 and reducing the risk of the first spacer portion 123 falling into the first opening 107, and the size of the third opening 109 is larger, which is conducive to the increase in the total opening area of the multiple third openings 109 in the first region, thereby increasing the infrared light transmittance of the first region.

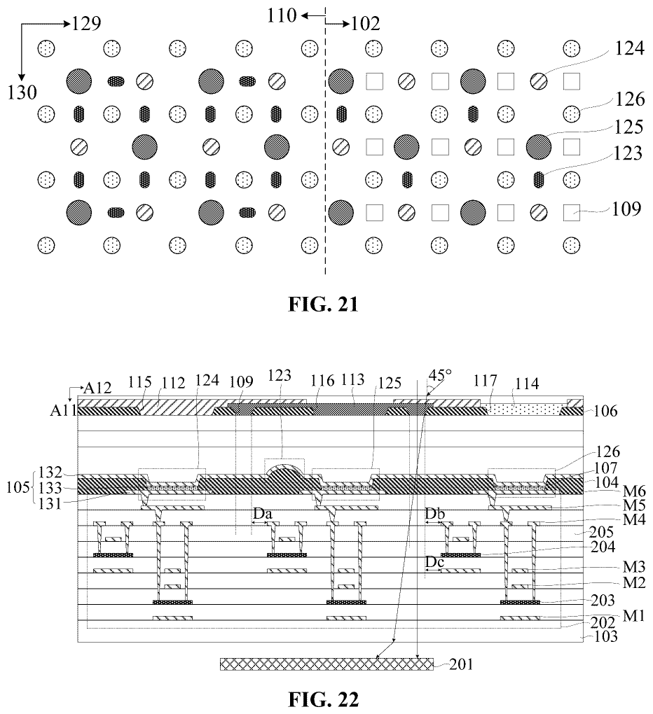

FIG. 21 is yet another diagram of a display panel according to an embodiment of the present disclosure. As shown in FIG. 21, the display region includes the second region 110; the density of first spacer portions 123 in the second region 110 is greater than or equal to the density of first spacer portions 123 in the first region 102. Optionally, in the first region 102, the density of the first spacer portions 123 is smaller than the density of the third openings 109. In FIG. 21, any one of the first color light-emitting element 124, the second color light-emitting element 125, or the third color light-emitting element 126 is the orthographic projection of the light-emitting region of a light-emitting element on the display region; the first spacer portion 123 is the orthographic projection of a side of the first spacer portion facing the pixel definition layer on the display region; the third opening 109 is the orthographic projection of the lower opening of the third opening on the display region.

In the display panel, the area proportion of the second region 110 in the display region is large, and the area proportion of the first region 102 in the display region is minimal. Therefore, the first spacer portions 123 in the second region 110 play a major role in supporting the display panel, while the first spacer portions 123 in the first region 102 with a small area have a small role or effect on supporting the display panel. Reducing the distribution density of the first spacer portions 123 in the first region 102 does not affect the overall supporting effect on the display panel. Based on this, optionally, the density of the first spacer portions 123 in the first region 102 is less than or equal to the density of the first spacer portions 123 in the second region 110.

In this embodiment, the density of the first spacer portions 123 in the first region 102 is designed to be smaller than the density of the first spacer portions 123 in the second region 110. Exemplarily, in the display region, the first spacer portion 123 is disposed within the non-opening region space between the adjacent first color light-emitting element 124 and second color light-emitting element 125 along the extension direction of the second virtual side 130, and in the second region 110, at least one first spacer portion 123 is disposed within the non-opening region space between the adjacent first color light-emitting element 124 and second color light-emitting element 125 along the extension direction of the first virtual side 129.

In the display panel, the area proportion of the second region 110 in the display region is large, and the third opening 109 is not required to be disposed between the adjacent first color light-emitting element 124 and second color light-emitting element 125 in the second region 110; the area proportion of the first region 102 in the display region is small, and at least one of the first spacer portion 123 or the third opening 109 is required to be disposed between the adjacent first color light-emitting element 124 and second color light-emitting element 125 in the first region 102. Therefore, the density of the first spacer portions 123 in the first region 102 is appropriately reduced so that more space in the non-opening region of the first region 102 can be provided for disposing the third opening 109, and the supporting effect on the display panel will not be affected. The area proportion of the first region 102 in the display region is small, which is not only used for display but also for transmitting light through the third opening 109 so that the first function device designed in the first region 102 can receive and send light with the exterior. Therefore, in the first region 102, the density of the first spacer portions 123 is designed to be smaller than the density of the third openings 109, which is conducive to the disposition of more third openings 109 in the non-opening region of the first region 102, increases the transmittance of the third opening 109, and is conducive to the increase in the transmittance of the first region 102. Optionally, the third opening 109 is disposed within the non-opening region space between the adjacent first color light-emitting element 124 and second color light-emitting element 125 along the extension direction of the first virtual side 129.

However, in other embodiments, optionally, the density of the first spacer portions in the second region is also equal to the density of the first spacer portions in the first region; and/or in the first region, the density of the first spacer portions is equal to the density of the third openings. These are not described in an embodiment.

FIG. 22 is yet another diagram of a display panel according to an embodiment of the present disclosure. As shown in FIG. 22, optionally, a light-emitting element 105 includes a first electrode 131, a second electrode 132, and a light-emitting layer 133 located between the first electrode 131 and the second electrode 132; the first electrode 131 is in the shape of a circle; along the first direction A11, the first electrode 131 covers the first opening 107. It is to be noted that the first electrode 131 in the shape of a circle is only an example, but this is not limited thereto. In other embodiments, the first electrode may also be designed to be in the shape of a quadrilateral, a polygon, or others. Along the first direction A11, the orthographic projection of the first electrode 131 covers the first opening 107. Based on this, the shape of the first electrode 131 may be the same as or different from the shape of the lower opening of the first opening 107.

In this embodiment, optionally, the display panel is the organic light-emitting display panel.

The pixel definition layer 104 and the multiple light-emitting elements 105 are located on the same side of the substrate 103. In the light-emitting element 105, the first electrode 131 may be an anode, and the second electrode 132 may be a cathode. The first electrode 131 may be an independent electrode, and first electrodes 131 of two adjacent light-emitting elements 105 are insulated from each other. The second electrode 132 may be a surface electrode, so a second electrode region corresponding to the light-emitting element 105 in the second electrode 132 is defined as the second electrode 132 of the light-emitting element 105, and second electrodes 132 of two adjacent light-emitting elements 105 are electrically connected. However, in other embodiments, the design and positions of the anode and cathode are not limited thereto.

The light-emitting layer 133 is located between the first electrode 131 and the second electrode 132. If the first color light-emitting element 124 is a red light-emitting element, the light-emitting layer 133 of the first color light-emitting element 124 may be configured to include a red light-emitting material; if the second color light-emitting element 125 is a blue light-emitting element, the light-emitting layer 133 of the second color light-emitting element 125 may be configured to include a blue light-emitting material; if the third color light-emitting element 126 is a green light-emitting element, the light-emitting layer 133 of the third color light-emitting element 126 may be configured to include a green light-emitting material. However, it is not limited to this.

It is to be understood that a first function layer may be further included between the first electrode 131 of the light-emitting element 105 and the light-emitting layer 133 of the light-emitting element 105 and that a second function layer may be further included between the second electrode 132 of the light-emitting element 105 and the light-emitting layer 133 of the light-emitting element 105. If the first electrode 131 is an anode, and the second electrode 132 is a cathode, the first function layer may include at least one of a hole injection layer, a hole transport layer, or an electron-blocking layer, and the second function layer may include at least one of an electron injection layer, an electron transport layer, or a hole-blocking layer. The film layer structure of the display panel further includes a protective layer on a side of the second electrode 132 facing away from the first electrode 131, which is not specifically illustrated and described.

Optionally, the display region further includes at least one metal layer located between the substrate 103 and the light-blocking layer 106, and a metal layer includes multiple metal portions; along the first direction A11, the third opening 109 does not overlap a metal portion. Optionally, along the second direction A12, the distance from the third opening 109 to the metal portion is greater than or equal to the first distance, and the second direction A12 intersects the first direction A11. Optionally, the first distance is equal to 3 μm.

In this embodiment, a pixel circuit structure is disposed between the substrate 103 of the display region and the pixel definition layer 104 of the display region, and the pixel circuit structure includes multiple pixel circuits; the pixel circuits are electrically connected to the light-emitting elements 105 to drive the light-emitting elements 105 to display. In an embodiment, the thin-film transistor array layer 202 is at least disposed between the substrate 103 and the pixel definition layer 104, and as part of the pixel circuit structure, the thin-film transistor array layer 202 is configured to drive the light-emitting elements 105 to display. The thin-film transistor array layer 202 includes the multiple thin-film transistors. In an embodiment, the thin-film transistor array layer 202 includes multiple array metal layers and interlayer insulating layers 205, and at least one insulating layer 205 is disposed between two adjacent array metal layers.

Optionally, the types of the transistors in the thin-film transistor array layer 202 are diverse, and metal oxide transistors (such as IGZO TFT) and low-temperature polysilicon transistors (such as LTPS TFT) may coexist. The metal oxide transistors have the advantages of low leakage current, and the low-temperature polysilicon transistors have the advantages of fast switching speed, high carrier mobility, and low power. In an embodiment, the thin-film transistor array layer 202 at least includes six array metal layers, the first active layer (POLY) 203, and the second active layer (IGZO) 204. The six array metal layers are marked as M1, M2, M3, M4, M5, and M6 sequentially. It is to be noted that FIG. 22 only shows some film layers between the substrate 103 and the pixel definition layer 104 and that other film layers are further included between the substrate 103 of the display panel and the pixel definition layer 104 of the display panel, which is not specifically limited or explained. Based on the specific film layer disposition of the display panel, adaptive adjustments may be made according to the actual production requirements such as adding or subtracting some film layers, which is not specifically limited in the embodiment of the present disclosure.

In this embodiment, multiple film layers in the thin-film transistor array layer 202 are used as an example for description. For any one of the six array metal layers M1 to M6, the metal layer includes the multiple metal portions, and different metal portions of the same metal layer may or may not be electrically connected. Along the first direction A11, the third opening 109 does not overlap the metal portion, so the external light passing through the third opening 109 is not blocked by the metal portion and may be incident on the first function device 201 so that the first function device 201 can sense the brightness of the external light through the third opening 109 and thereby adjust the brightness of the screen.

In addition, light actually collected and detected by the first function device 201 includes not only collimated incident light, but also light with a certain angle range to increase the detection accuracy. Usually, customers have considered specifications for the attenuation of the transmittance at a large viewing angle, and the requirement is that the attenuation ratio of the transmittance intensity of light at 45° to the transmittance intensity of orthographic-viewing angle light be less than 55%. Along the first direction A11, the smaller the distance from the third opening 109 to the metal portion, the more of large-viewing angle light is incident on the metal portion and absorbed so that the transmittance attenuation of the large-viewing angle light can be faster, and the reflectance can increase.

Based on this, along the first direction A11, the distance from the third opening 109 to the metal portion is designed to be greater than or equal to the first distance, so the large-viewing angle light at 45° cannot be incident on the metal portion and absorbed, or the large-viewing angle light at 45° can be only partially incident on the metal portion and absorbed so that the attenuation ratio of the transmittance intensity of the large-viewing angle light at 45° to the transmittance intensity of the orthographic-viewing angle light can be less than 55%, and the reflectance increase in the third opening compared to a non-punching region can be small. It can be seen that the distance from the third opening 109 to the metal portion is designed to be greater than or equal to the first distance so that the light actually collected and detected by the first function device 201 can include not only the collimated incident light, but also the light with a certain angle range, thereby increasing the detection accuracy.

Optionally, the first distance is equal to 3 μm. As shown in FIG. 22, along the second direction A12, the minimum distance Da from the third opening 109 to the metal portion is greater than or equal to 3 μm.

Optionally, the minimum distance Da from the third opening 109 to the metal portion is also greater than or equal to 3 μm and less than or equal to 6 μm. It is to be understood that if the minimum distance Da from the third opening 109 to the metal portion is greater than or equal to 6 μm, the resolution PPI is easily affected.

It is to be noted that, optionally, the third opening 109 includes a third upper opening, a third lower opening, and the third inner sidewall connected between the third upper opening and the third lower opening; along the first direction A11, the third lower opening is adjacent to the metal layer; along the second direction A12, the distance from the third lower opening to the metal portion is greater than or equal to the first distance, where the second direction A12 intersects the first direction A11. In this embodiment, along the second direction A12, the distance from the third opening 109 to the metal portion is the distance from the lower opening of the third opening 109 to the metal portion.

It is to be noted that for the second electrode 132, optionally, the second electrode 132 is an electrode that may transmit the infrared light. Alternatively, for the second electrode 132, optionally, the second electrode 132 has a mesh corresponding to the third opening 109. In an embodiment, along the first direction A11, the mesh of the second electrode 132 surrounds the corresponding third opening 109, and the distance from the mesh of the second electrode 132 to the corresponding third opening 109 is greater than or equal to the first distance.

As shown in FIG. 22, optionally, the at least one metal layer includes a first metal layer and a second metal layer, the second metal layer is located between the substrate 103 and the first metal layer, and the second metal layer includes multiple second metal portions; along the second direction A12, the distance from the third opening 109 to a second metal portion is larger than the first distance. Optionally, the first metal layer is located between the substrate 103 and the pixel definition layer 104.

In this embodiment, optionally, the first metal layer is the metal layer M4, the second metal layer is the metal layer M3, and the first metal layer M4 and the second metal layer M3 are located between the substrate 103 and the pixel definition layer 104. The second metal layer M3 is located between the substrate 103 and the first metal layer M4.

The first metal layer M4 includes multiple first metal portions, and the second metal layer M3 includes multiple second metal portions. Therefore, along the first direction A11, the third opening 109 does not overlap a first metal portion in the first metal layer M4, and along the second direction A12, the distance Db from the third opening 109 to the first metal portion in the first metal layer M4 is greater than or equal to 3 μm; this distance Db may be the minimum distance from the third opening 109 to the first metal portion in the first metal layer M4. Similarly, along the first direction A11, the third opening 109 does not overlap a second metal portion in the second metal layer M3, and along the second direction A12, the distance Dc from the third opening 109 to the second metal portion in the second metal layer M3 is greater than or equal to 3 μm; this distance Dc may be the minimum distance from the third opening 109 to the second metal portion in the second metal layer M3.

In this embodiment, Db is greater than or equal to 3 μm, and Dc is greater than or equal to 3 μm. Based on this, Db may be equal to Dc, Db may be smaller than Dc, or Db may be larger than Dc.

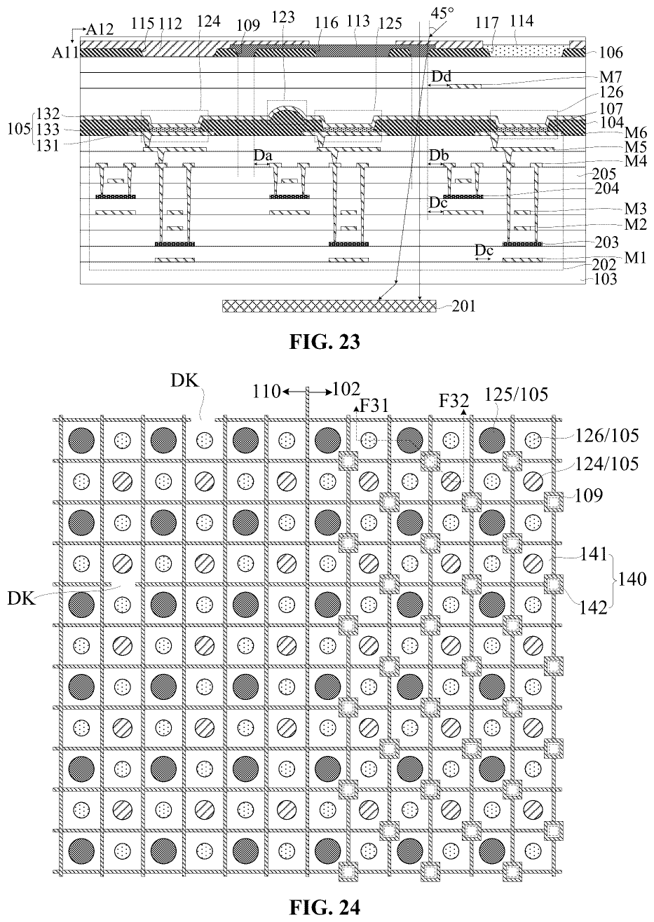

FIG. 23 is yet another diagram of a display panel according to an embodiment of the present disclosure. Different from FIG. 22, the at least one metal layer is included between the pixel definition layer 104 and the light-blocking layer 106 in FIG. 23 and includes a metal layer M7. Optionally, the first metal layer is located between the pixel definition layer 104 and the light-blocking layer 106. Optionally, the second metal layer is located between the first metal layer and the pixel definition layer 104, or the second metal layer is located between the substrate 103 and the pixel definition layer 104.

In this embodiment, optionally, the first metal layer is the metal layer M7, and the second metal layer is the metal layer M3. Therefore, along the first direction A11, the third opening 109 does not overlap a first metal portion in the first metal layer M7, and along the second direction A12, the distance Dd from the third opening 109 to the first metal portion in the first metal layer M7 is greater than or equal to 3 μm; this distance Dd may be the minimum distance from the third opening 109 to the first metal portion in the first metal layer M7. In this embodiment, Dd is greater than or equal to 3 μm, and Dc is greater than or equal to 3 μm. Based on this, Dd may be equal to Dc, Dd may be smaller than Dc, or Dd may be larger than Dc.

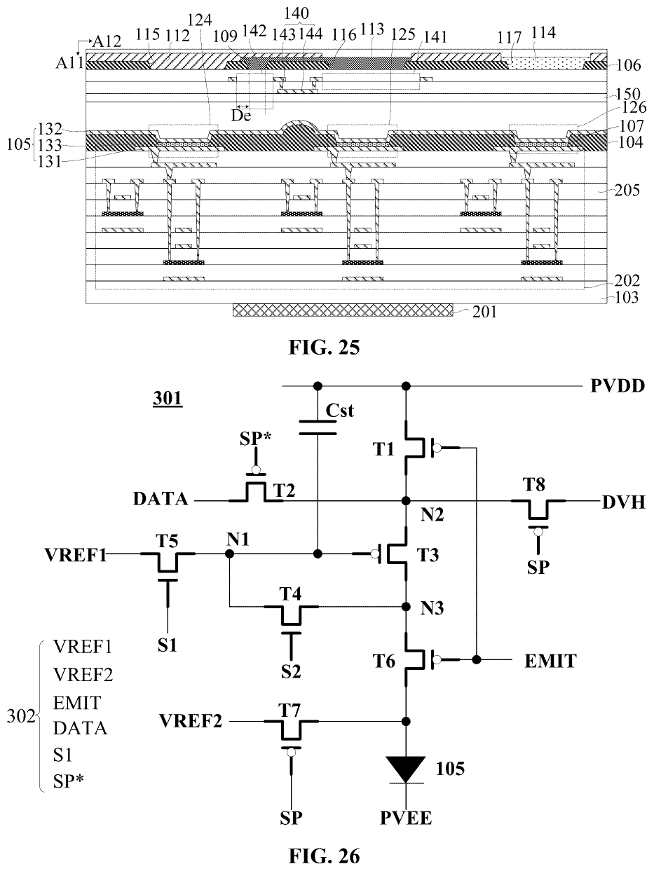

FIG. 24 is yet another diagram of a display panel according to an embodiment of the present disclosure. FIG. 25 is a partial cross-sectional view taken along F31-F32 of FIG. 24. As shown in FIGS. 24 and 25, optionally, the at least one metal layer includes a third metal layer 140 located between the pixel definition layer 104 and the light-blocking layer 106; the third metal layer 140 includes multiple third metal portions, and at least one third metal portion each includes multiple first meshes 141; along the first direction A11, at least one first mesh 141 surrounds at least one light-emitting element 105. Optionally, the at least one third metal portion each includes multiple second meshes 142; along the first direction A11, at least one second mesh 142 surrounds at least one third opening 109. Optionally, the display region further includes an encapsulation layer 150 located between the pixel definition layer 104 and the light-blocking layer 106; the third metal layer 140 is located between the encapsulation layer 150 and the light-blocking layer 106. Optionally, the multiple third metal portions include electrode portions 143 and bridge portions 144. The electrode portions 143 each include the multiple first meshes 141. At least two first meshes 141 are electrically connected through a bridge portion 144. In FIG. 24, optionally, the orthographic projection of the third opening 109 along the direction A11 is a rectangle, which is not limited to this. The rectangular third opening is only an example.

In this embodiment, the encapsulation layer 150 is located between the pixel definition layer 104 and the light-blocking layer 106, and the third metal layer 140 is located between the encapsulation layer 150 and the light-blocking layer 106. The third metal layer 140 may be used as a touch electrode metal layer. The touch electrode metal layer is made on the encapsulation layer in the display panel, which is conducive to the thinning of the display panel and is also suitable for the production of a flexible screen.

The third metal layer 140 includes the multiple third metal portions, and the multiple third metal portions include the multiple electrode portions 143 and the multiple bridge portions 144. The multiple electrode portions 143 are located in the same layer, and the multiple bridge portions 144 are located in the same layer. The electrode portions 143 and the bridge portions 144 are located in different layers, and different electrode portions 143 are insulated from each other. An electrode portion 143 includes the multiple first meshes 141 electrically connected, and the at least two first meshes 141 in the electrode portion 143 are electrically connected through the bridge portion 144.

FIG. 24 shows the electrode portions 143 of the third metal layer 140. It is to be noted that the third metal layer 140 includes the multiple electrode portions 143, and the different electrode portions 143 are insulated from each other. In an embodiment, breaks DK are disposed between the different electrode portions 143 for insulation. FIG. 24 shows only two breaks DK in the third metal layer 140. It is to be understood that the third metal layer 140 in FIG. 24 further includes multiple breaks DK, but none of them are shown in the figure. The multiple breaks DK are disposed in the third metal layer 140 so that the different electrode portions 143 can be insulated from each other. The positions and number of breaks DK between the different electrode portions 143 may be reasonably designed according to the requirements of the product. The electrode portion 143 includes the multiple first meshes 141 electrically connected, and along the first direction A11, a first mesh 141 surrounds at least one light-emitting element 105. In addition, in FIG. 25, only part of one electrode portion 143 is shown in the film layer where the electrode portions are located, and only part of one bridge portion is shown in the film layer where the bridge portions are located.

The electrode portion 143 includes the multiple first meshes 141. At least one electrode portion 143 each includes not only the multiple first meshes 141 electrically connected but also the at least one second mesh 142. Along the first direction A11, the at least one first mesh 141 surrounds the at least one light-emitting element 105; along the first direction A11, the at least one second mesh 142 surrounds the at least one third opening 109. It can be seen that along the first direction A11, the third opening 109 does not overlap a third metal portion in the third metal layer 140, so when passing through the third opening 109, the external light is not blocked by the third metal portion and can be incident on the first function device 201 so that the first function device 201 can sense the brightness of the external light through the third opening 109 and thereby adjust the brightness of the screen.

Along the first direction A11, the distance De from the third opening 109 to the boundary of a second mesh 142 is designed to be greater than or equal to the first distance, so the large-viewing angle light at 45° cannot be incident on the third metal portion and absorbed, or the large-viewing angle light at 45° can be only partially incident on the third metal portion and absorbed so that the light actually collected and detected by the first function device 201 can include not only the collimated incident light, but also the light with a certain angle range, thereby increasing the detection accuracy. Optionally, the minimum distance De from the third opening 109 to the boundary of the second mesh 142 is greater than or equal to 3 μm and less than or equal to 6 μm.

It is to be noted that the meshes in the third metal layer may also be formed by multiple metal wires that cross each other. In an embodiment, the multiple third metal portions in the third metal layer may be divided into multiple parallel first metal wires and multiple parallel second metal wires; the first metal wires and the second metal layer are stacked and insulated; the multiple first metal wires and the multiple second metal wires cross, so the multiple first metal wires and the multiple second metal wires cross along the first direction to define the multiple meshes.

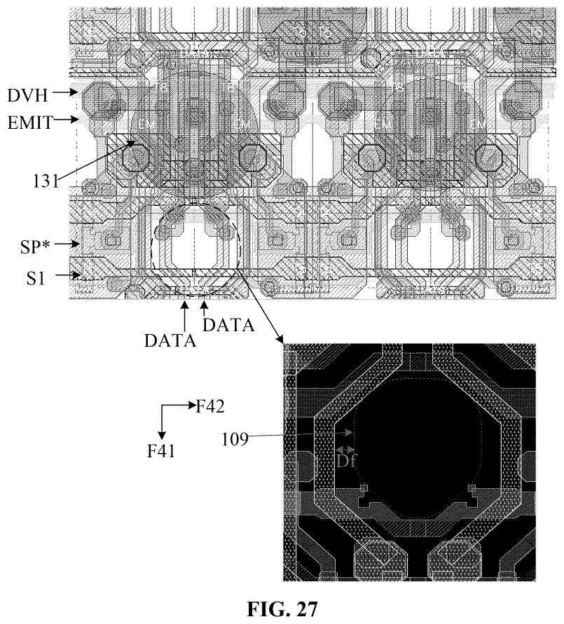

FIG. 26 is a diagram of a pixel circuit according to an embodiment of the present disclosure. FIG. 27 is yet another diagram of a display panel according to an embodiment of the present disclosure. As shown in FIGS. 25 to 27, optionally, the display region includes multiple pixel circuits 301 and multiple signal lines 302; a pixel circuit 301 includes at least one transistor, and a transistor includes a source and a drain; the multiple signal lines 302 include multiple data signal lines DATA, and a data signal line DATA is electrically connected to the source of the transistor of the at least one transistor or the drain of the transistor of the at least one transistor; along the first direction A11, the orthographic projection of the third opening 109 on the plane on which the substrate 103 is located is located between two adjacent data signal lines DATA. Optionally, the multiple data signal lines DATA extend along the first sub-direction F41 and are arranged along the second sub-direction F42, and the first sub-direction F41 and the second sub-direction F42 intersect and both intersect the first direction A11; along the second sub-direction F42, the third opening 109 includes a first edge and a second edge that are opposite to each other; along the second sub-direction F42, the distance Df from any one of the first edge or the second edge to the most adjacent data signal line DATA is greater than or equal to the first distance.

The pixel circuit 301 is disposed in a variety of ways. In this embodiment, the pixel circuit 301 is illustrated using an “8T1C” structure as an example, where “T” denotes a transistor, and “C” denotes a storage capacitor. Those skilled in the art may adaptively adjust the pixel circuit according to the requirements, and the pixel circuit is not limited to the “8T1C” structure. The pixel circuit 301 includes multiple transistors, in an embodiment, a drive transistor T3 and a data write transistor T2. The signal lines 302 include the multiple data signal lines DATA extending along the first sub-direction F41 and arranged along the second sub-direction F42. The data write transistor T2 is coupled between a data signal line DATA and a first electrode N2 of the drive transistor T3. In an embodiment, optionally, one of the source of the data write transistor T2 or the drain of the data write transistor T2 is electrically connected to the data signal line DATA, and the other one of the source of the data write transistor T2 or the drain of the data write transistor T2 is electrically connected to the first electrode N2 of the drive transistor T3.

Along the first direction A11, the orthographic projection of the third opening 109 on the plane on which the substrate 103 is located is located between the two adjacent data signal lines DATA. The light-emitting element 105 includes the first electrode 131. Along the first direction A11, the first electrode 131 and the data signal line DATA have an overlapping portion. For a portion of the data signal line DATA that does not overlap the first electrode 131, the third opening 109 may be disposed between the two adjacent data signal lines DATA so that the orthographic projection of the third opening 109 on the plane on which the substrate 103 is located can be located between the two adjacent data signal lines DATA.

Along the second sub-direction F42, the third opening 109 includes the first edge and the second edge that are opposite to each other; along the second sub-direction F42, the distance Df from the any one of the first edge or the second edge to the most adjacent data signal line DATA is greater than or equal to the first distance. When the large-viewing angle light passes through the third opening 109, the risk of being blocked by the metal wires in the display panel is reduced so that the light with a certain angle range can pass through the third opening 109 and gaps in the metal layers of the display panel and enter the first function device 201, thereby increasing the detection accuracy of the first function device 201. Optionally, Df is greater than or equal to 3 μm and less than or equal to 6 μm.

As shown in FIGS. 25 to 27, optionally, the display region includes the multiple pixel circuits 301 and the multiple signal lines 302; the pixel circuit 301 includes the at least one transistor, and the transistor includes a gate; the multiple signal lines 302 include multiple gate signal lines, and a gate signal line is electrically connected to the gate of the transistor of the at least one transistor; along the first direction A11, the orthographic projection of the third opening 109 on the plane on which the substrate 103 is located is adjacent to at least one gate signal line. Optionally, the multiple gate signal lines extend along the second sub-direction F42 and are arranged along the first sub-direction F41, and the first sub-direction F41 and the second sub-direction F42 intersect and both intersect the first direction A11; along the first sub-direction F41, the third opening 109 includes a third edge and a fourth edge that are opposite to each other; along the first sub-direction F41, the distance from any one of the third edge or the fourth edge to the most adjacent gate signal line is greater than or equal to the first distance.

The pixel circuit 301 includes multiple transistors, in an embodiment, a first reset transistor T5, a first dimming transistor T1, and a second dimming transistor T2. The signal lines 302 include the multiple gate signal lines extending along the second sub-direction F42 and arranged along the first sub-direction F41. Optionally, the multiple gate signal lines at least include a first scan line S1, a second scan line SP*, and a dimming control line EMIT. The first scan line S1 is connected to the gate of the first reset transistor T5 to control the first reset transistor T5 to turn on or off. The second scan line SP* is connected to the gate of the data write transistor T2 to control the data write transistor T2 to turn on or off. The dimming control line EMIT is connected to the gate of the first dimming transistor T1 to control the first dimming transistor T1 to turn on or off, and/or the dimming control line EMIT is connected to the gate of the second dimming transistor T2 to control the second dimming transistor T2 to turn on or off.

Along the first direction A11, the orthographic projection of the third opening 109 on the plane on which the substrate 103 is located is located between two adjacent gate signal lines. In an embodiment, optionally, along the first direction A11, the orthographic projection of the third opening 109 on the plane on which the substrate 103 is located is located between the first scan line S1 and the second scan line SP*.

Along the first sub-direction F41, the third opening 109 includes the third edge and the fourth edge that are opposite to each other; along the first sub-direction F41, the distance (not shown) from the any one of the third edge or the fourth edge to the most adjacent gate signal line is greater than or equal to the first distance. When the large-viewing angle light passes through the third opening 109, the risk of being blocked by the metal wires in the display panel is reduced so that the light with a certain angle range can pass through the third opening 109 and the gaps in the metal layers of the display panel and enter the first function device 201, thereby increasing the detection accuracy of the first function device 201. Optionally, the distance from the any one of the third edge or the fourth edge to the most adjacent gate signal line is greater than or equal to 3 μm and less than or equal to 6 μm.

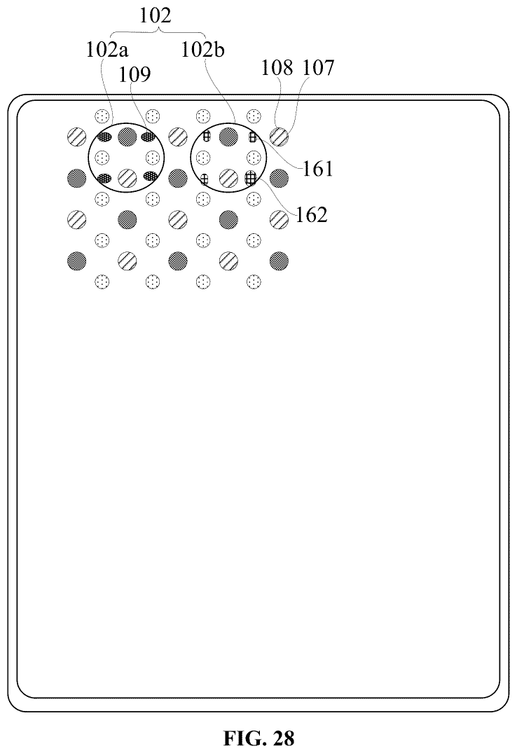

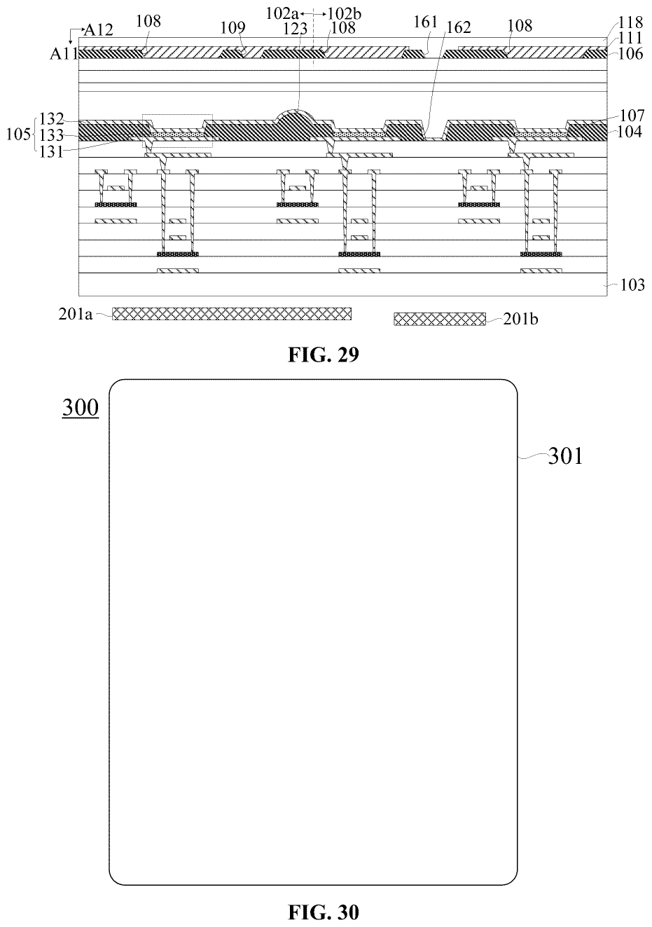

FIG. 28 is yet another diagram of a display panel according to an embodiment of the present disclosure. FIG. 29 is yet another diagram of a display panel according to an embodiment of the present disclosure. As shown in FIGS. 28 and 29, optionally, in the first region 102, the light-blocking layer 106 further has at least one fourth opening 161, and the pixel definition layer 104 has at least one fifth opening 162; along the first direction A11, the at least one fourth opening 161 overlaps the at least one fifth opening 162 and does not overlap the first openings 107. In FIG. 28, the first region 102, fourth openings 161, the third openings 109, the second openings 108, and the first openings 107 are all orthographic projections of the structures along the direction A11. FIG. 29 shows the overlapping relationship between the fourth openings 161 and fifth openings 162, which does not represent the actual size relationship. The relationship between the fourth openings 161 and the fifth openings 162 may be designed as “greater than”, “less than”, or “equal to” according to the requirements of the product.

It is to be noted that for a fourth opening 161, along the second direction A12, the distance from the fourth opening 161 to a metal portion in any metal layer is greater than or equal to the first distance. In other words, along the first direction A11, a metal wire of any metal layer between the substrate 103 and the light-blocking layer 106 is designed to be wound around the fourth opening 161 to prevent the metal wire from blocking light passing through the fourth opening 161. Similarly, along the first direction A11, a metal wire of any metal layer between the substrate 103 and the light-blocking layer 106 is designed to be wound around a fifth opening 162 to prevent the metal wire from blocking light passing through the fifth opening 162.

In this embodiment, the at least one fourth opening 161 is further newly added to the light-blocking layer 106, and the at least one fifth opening 162 is further newly added to the pixel definition layer 104. Optionally, the fourth opening 161 is in the shape of a polygonal or a circle. As shown in FIG. 28, optionally, the fourth opening 161 is in the shape of a rounded rectangle, which is not limited thereto.

In an embodiment, at least one third opening 109 and at least one fourth opening 161 are disposed in a region other than the second openings 108 of the light-blocking layer 106, and light emitted by the light-emitting elements 105 is emitted through the second openings 108.

Optionally, the fourth opening 161 is configured to transmit light in a waveband centered at 550 nm; the third opening 109 is configured to transmit light in a waveband centered at 940 nm. In an embodiment, the first region 102 includes an infrared transmitting region 102a and an LS hole 102b; the infrared transmitting region 102a is an infrared light projection hole, and the LS hole 102b is a visible light projection hole; the infrared transmitting region 102a is provided with one or more third openings 109, and the LS hole 102b is provided with one or more fourth openings 161.

In an embodiment, the third opening 109 is configured to transmit light in a waveband centered at the 940 nm. Along the first direction A11, the third opening 109 does not overlap the first opening 107, and the orthographic projection of the third opening 109 on the pixel definition layer 104 is located in the non-opening region of the pixel definition layer 104, that is, the pixel definition layer region corresponding to the orthographic projection of the third opening 109 does not have an opening. Therefore, the third opening 109 does not affect the light-emitting region of the light-emitting element 105, thereby ensuring the normal display function of the display panel. Moreover, at least one color filter in the color filter layer 111 fills the third opening 109 so that the third opening 109 can have a high transmittance in the infrared light waveband, but the third opening 109 does not transmit the visible light basically. Therefore, the first function device 201 in the first region 102 may include the infrared light sensor 201a for sensing the infrared light; the infrared light sensor 201a overlaps the at least one third opening 109 along the first direction A11.

In an embodiment, the fourth opening 161 is configured to transmit light in a waveband centered at the 550 nm. Along the first direction A11, the fourth opening 161 does not overlap the first opening 107, and the orthographic projection of the fourth opening 161 on the pixel definition layer 104 overlaps the fifth opening 162. In other words, a pixel definition layer region corresponding to the orthographic projection of the fourth opening 161 is added with the corresponding fifth opening 162. Therefore, the fourth opening 161 does not affect the light-emitting region of a light-emitting element 105, thereby ensuring the normal display function of the display panel. Moreover, the color filter layer 111 does not fill the fourth opening 161, and the fourth opening 161 may transmit visible light. In an embodiment, the visible light may enter the display panel through the fourth opening 161 and the fifth opening 162, or the light emitted by the first function device 201 is emitted to the exterior of the display panel through the fifth opening 162 and the fourth opening 161. Therefore, the first function device 201 in the first region 102 may also include the optical devices such as the camera 201b for sensing the visible light, and the camera 201b overlaps the at least one fourth opening 161 along the first direction A11.

In an embodiment, along the first direction A11, optionally, the fourth opening 161 overlaps the fifth opening 162; or according to the requirements of the product, the orthographic projection of the fourth opening 161 may be designed to cover the fifth opening 162; or according to the requirements of the product, the orthographic projection of the fifth opening 162 may be designed to cover the fourth opening 161.

In an embodiment, after the manufacturing process of the color filter layer 111, a photoresist layer 118 is coated on the color filter layer 111. Optionally, a transparent photoresist material directly fills the fourth opening 161, so the fourth opening 161 may be used as a visible light photosensitive opening to transmit the visible light. In an embodiment, the fourth opening 161 filled with the transparent photoresist material has a high transmittance of 550 nm and meets the transmittance requirement of the visible light. The optical devices disposed in the first region 102 may include a light sensor. Along the first direction A11, the light sensor overlaps at least one visible light photosensitive opening. The at least one visible light photosensitive opening may allow the visible light to pass through, so the light sensor can adjust the brightness of the screen of the display device according to the brightness of surrounding light. Adding the at least one fourth opening 161 to the first region 102 can increase the transmittance of the first region 102. While the normal display of the first region 102 is ensured, the first region 102 is further allowed to achieve a better light transmission effect so that the sensing sensitivity and accuracy of the light sensor in the first region 102 can be increased, thereby achieving a better brightness adjustment effect.

It is to be noted that the first region 102 includes multiple fourth openings 161; optionally, the transparent photoresist material fills the multiple fourth openings 161, so the first region 102 fulfills the visible light transmission function, which is conducive to the disposition of the optical devices for sensing the visible light, such as an under-screen camera, in the first region 102.

In this embodiment, a fourth opening 161 is added to the light-blocking layer 106, and a corresponding fifth opening 162 is added to a pixel definition layer region corresponding to the fourth opening 161. The third opening 109 may be configured to transmit the infrared light, and the fourth opening 161 may be configured to transmit the visible light. Based on this, the infrared light transmittance and visible light transmittance of the first region 102 can be increased so that the first region 102 can include not only the infrared transmitting region 102a for sensing the infrared light but also the LS hole 102b for sensing the visible light.

Optionally, along the first direction A11, the fourth opening 161 does not overlap a color filter in the color filter layer 111 and the light-emitting element 105.

In this embodiment, in the manufacturing process of the color filter layer 111, a color filter material may fill the second opening 108 and the third opening 109, but the fourth opening 161. Therefore, along the first direction A11, the fourth opening 161 does not overlap the color filter in the color filter layer 111 so that the fourth opening 161 can transmit the visible light.

Along the first direction A11, the fourth opening 161 does not overlap the first opening 107. In an embodiment, the fourth opening 161 does not overlap the light-emitting element 105, and the second opening 108 overlaps the first opening 107. Therefore, the light emitted by the light-emitting element 105 is emitted through the second opening 108 in the light-blocking layer 106; the large-angle light emitted by the light-emitting element 105 is blocked by the non-opening region of the light-blocking layer 106 and the color filters in the third opening 109, and no light leaks. Even if the light-emitting element 105 leaks light from the fourth opening 161, since the area proportion of the fourth opening 161 in the first region 102 is minimal, the impact of the light intensity leaked from the fourth opening 161 on the display effect of the display panel may also be ignored.

Optionally, along the first direction A11, the area of the orthographic projection of the fourth opening 161 is less than or equal to the area of the orthographic projection of the third opening 109. Optionally, the pixel definition layer 104 includes the multiple first spacer portions 123; along the first direction A11, the fourth opening 161 does not overlap a first spacer portion 123. Optionally, along the first direction A11, the orthographic projection of the fourth opening 161 is located in the fifth opening 162.

In this embodiment, along the first direction A11, a fifth opening 162 is disposed in a pixel definition layer region in which the orthographic projection of the fourth opening 161 is located, and a pixel definition layer region in which the first spacer portion 123 is located is a non-opening region of the pixel definition layer 104, so along the first direction A11, the fourth opening 161 does not overlap the first spacer portion 123.

The fourth opening 161 and the third opening 109 are added to the light-blocking layer 106. Along the first direction A11, the orthographic projection of the third opening 109 and the first spacer portion 123 are located in the non-opening region of the pixel definition layer 104. Along the first direction A11, a pixel definition layer region corresponding to the orthographic projection of the fourth opening 161 is provided with the fifth opening 162. Optionally, along the first direction A11, the third opening 109 does not overlap the first spacer portion 123. Therefore, along the first direction A11, the orthographic projection of the third opening 109, the fifth opening 162, and the first spacer portion 123 jointly occupy a pixel definition layer region other than the first opening 107 in the pixel definition layer 104.

If the area of the orthographic projection of the fourth opening 161 along the first direction A11 is too large, the area of the corresponding fifth opening 162 is adaptively increased, which occupies the position space of the first spacer portion 123 and/or the third opening 109. Based on this, for the position space of the first spacer portion 123 being occupied, the first spacer portion 123 is caused to easily fall into the first opening 107 due to a too-close distance from the first spacer portion 123 to the first opening 107, affecting the display effect; or reducing the size of the first spacer portion 123 in the first region 102 or the number of first spacer portions 123 in the first region 102 reduces the supporting effect of the first spacer portions 123. For the position space of the third opening 109 being occupied, reducing the size of the third opening 109 or the number of third openings 109 affects the infrared light transmittance of the first region 102.

Exemplarily, using the current mobile phone of the conventional size as an example, the light-blocking layer 106 of the display panel of the mobile phone is provided with the fourth opening 161, and the opening size of the fourth opening 161 may be 8.63 μm*12.46 μm; the opening area of the fifth opening 162 may be greater than 76 μm², and/or the opening area of the fifth opening 162 may be greater than the opening area of the fourth opening 161; the opening area of the third opening 109 may be greater than 91 μm².

It can be seen that if the area of the fourth opening 161 is designed to be small, the area of the corresponding fifth opening 162 is adaptively reduced, which can reduce the space occupied by the fifth opening 162 in the pixel definition layer 104, thereby being conducive to the provision of more position space for the first spacer portion 123 and the third opening 109 in the pixel definition layer 104. The display effect of the display panel and the light transmittance of the first region 102 can be ensured.

Based on the same application concept, an embodiment of the present disclosure further provides a display device. The display device includes any display panel provided in the preceding embodiments. FIG. 30 is a diagram of a display device according to an embodiment of the present disclosure. As shown in FIG. 30, the display device 300 includes the display panel 301. Therefore, the display device 300 also has the beneficial effects of the display panel 301 described in the preceding embodiments. For the same details, reference may be made to the description of the preceding display panel 301, and details are not repeated herein.

The display device 300 provided in the embodiment of the present disclosure may be a mobile phone shown in FIG. 30, or may also be any electronic product with a display function, including, but not limited to, a television, a laptop, a desktop display, a tablet computer, a digital camera, a smart bracelet, smart glasses, an in-vehicle display, industry-controlling equipment, a medical display screen, or a touch interactive terminal, which is not specifically limited in the embodiment of the present disclosure.

It is to be understood that various forms of processes shown in the preceding may be adopted with steps reordered, added, or deleted. For example, the steps described in the present disclosure may be performed in parallel, sequentially or in different sequences, as long as the desired results of the technical solutions of the present disclosure can be achieved, and no limitation is imposed herein.

The preceding embodiments do not limit the scope of the present disclosure. It is to be understood by those skilled in the art that various modifications, combinations, sub-combinations, and substitutions may be performed according to design requirements and other factors. Any modification, equivalent substitution, improvement or the like that is made within the spirit and principle of the present disclosure is within the scope of the present disclosure.

What is claimed is:

1. A display panel, comprising a display region and a first region located within the display region,
wherein the display region comprises a substrate, a pixel definition layer, a plurality of light-emitting elements, and a light-blocking layer that are disposed sequentially; the pixel definition layer has a plurality of first openings, and the light-blocking layer has a plurality of second openings; the plurality of light-emitting elements are located in the plurality of first openings respectively;
wherein the light-blocking layer in the first region further has at least one third opening; and
wherein along a first direction, the plurality of second openings overlap the plurality of first openings respectively, and the at least one third opening does not overlap the plurality of first openings; the first direction is parallel to a stacking direction of film layers in the display region.

2. The display panel of claim 1, wherein the display region further comprises a color filter layer located on a side of the light-blocking layer facing away from the pixel definition layer; the color filter layer comprises a first color filter, a second color filter, and a third color filter; and
the plurality of second openings comprise a first color filter opening, a second color filter opening, and a third color filter opening; the first color filter is at least located in the first color filter opening, the second color filter is located in the second color filter opening, and the third color filter is located in the third color filter opening.

3. The display panel of claim 2, wherein the first color filter is further located in a third opening of the at least one third opening.

4. The display panel of claim 3, wherein the second color filter is further located in the third opening of the at least one third opening; and
along the first direction, the first color filter and the second color filter overlap in the third opening.

5. The display panel of claim 4, wherein in the third opening, the second color filter is located between the first color filter and the pixel definition layer.

6. The display panel of claim 4, wherein for the third opening, along the first direction, the second color filter covers the third opening, and the first color filter covers the second color filter.

7. The display panel of claim 3, wherein along the first direction, the first color filter covers at least one of the plurality of second openings and the at least one third opening.

8. The display panel of claim 4, wherein the second color filter located in the second color filter opening extends to overlap the at least one third opening.

9. The display panel of claim 2, wherein the first color filter is a red color filter; and
the second color filter is one of a green color filter or a blue color filter, and the third color filter is the other one of the green color filter or the blue color filter.

10. The display panel of claim 2, wherein in the first region, an area of the light-blocking layer in a plan view is Sa, an area of the first color filter in the plan view is Sb, and Sb/Sa≥50%.

11. The display panel of claim 3, wherein along the first direction, a color filter film thickness of any one of the plurality of second openings or the third opening is greater than or equal to 2.5 μm and less than or equal to 4 μm.

12. The display panel of claim 4, wherein in the third opening, a film thickness of the first color filter is different from a film thickness of the second color filter.

13. The display panel of claim 4, wherein in the third opening, a film thickness of the first color filter is smaller than a film thickness of the second color filter.

14. The display panel of claim 4, wherein in the third opening, a film thickness of the first color filter is greater than or equal to 0.7 μm and less than or equal to 2 μm.

15. The display panel of claim 4, wherein in the third opening, a film thickness of the second color filter is greater than or equal to 2 μm and less than or equal to 3 μm.

16. The display panel of claim 3, wherein along the first direction, a color filter film thickness of any one of the plurality of second openings or the third opening is greater than or equal to 2.5 μm and less than or equal to 3.5 μm.

17. The display panel of claim 4, wherein in the third opening, a film thickness of the first color filter is greater than or equal to 1 μm and less than or equal to 2 μm.

18. The display panel of claim 4, wherein in the third opening, a film thickness of the second color filter is greater than or equal to 1 μm and less than or equal to 3 μm.

19. The display panel of claim 1, wherein in the first region, an area of the light-blocking layer in a plan view is Sa, and an area of a third opening of the at least one third opening in the plan view is Sc; and
Sc/Sa≤10%.

20. The display panel of claim 1, wherein the pixel definition layer comprises a first non-opening region; and
in a plan view, a third opening of the at least one third opening is located in the first non-opening region.

21. The display panel of claim 20, wherein the pixel definition layer comprises a plurality of first spacer portions; and
the at least one third opening does not overlap the plurality of first spacer portions along the first direction.

22. The display panel of claim 21, wherein the plurality of first spacer portions overlap the first non-opening region along the first direction.

23. The display panel of claim 1, wherein the display region further comprises an active layer located between the substrate and the light-blocking layer; and
the at least one third opening does not overlap the active layer along the first direction.

24. The display panel of claim 1, wherein the first region comprises a first function device located on a side of the substrate facing away from the light-blocking layer; and
the at least one third opening overlaps the first function device along the first direction.

25. The display panel of claim 1, wherein the pixel definition layer is a black pixel definition layer.

26. The display panel of claim 1, wherein a third opening of the at least one third opening is in a shape of a polygon or a circle.

27. The display panel of claim 1, wherein the plurality of light-emitting elements comprise first color light-emitting elements, second color light-emitting elements, and third color light-emitting elements;
two first color light-emitting elements of the first color light-emitting elements and two second color light-emitting elements of the second color light-emitting elements form a first virtual quadrilateral; the two first color light-emitting elements are located at first vertexes of the first virtual quadrilateral respectively, and the two second color light-emitting elements are located at second vertexes of the first virtual quadrilateral respectively; the first vertexes and the second vertexes in the first virtual quadrilateral are alternately spaced apart; one of the third color light-emitting elements is located within the first virtual quadrilateral; and
four third color light-emitting elements of the third color light-emitting elements form a second virtual quadrilateral, the four third color light-emitting elements are located at vertexes of the second virtual quadrilateral respectively, and one of the first color light-emitting elements or one of the second color light-emitting elements is located within the second virtual quadrilateral.

28. The display panel of claim 27, wherein in a plan view, a third opening of the at least one third opening is located between adjacent first-color light-emitting element and second-color light-emitting element.

29. The display panel of claim 28, wherein the first virtual quadrilateral comprises a first virtual side and a second virtual side that are connected to each other; and
in the plan view, the third opening is located between a first color light-emitting element and a second color light-emitting element that are connected to the first virtual side.

30. The display panel of claim 27, wherein the pixel definition layer comprises a plurality of first spacer portions; and
a first spacer portion of the plurality of first spacer portions is located between adjacent first color light-emitting element and second color light-emitting element.

31. The display panel of claim 30, wherein the first virtual quadrilateral comprises a first virtual side and a second virtual side that are connected to each other; and
in the first region, the first spacer portion is located between a first color light-emitting element and a second color light-emitting element that are connected to the second virtual side.

32. The display panel of claim 31, wherein along a direction of the first virtual side, a size of a third opening of the at least one third opening is greater than or equal to a size of the first spacer portion; and
along a direction of the second virtual side, the size of the third opening is greater than or equal to the size of the first spacer portion.

33. The display panel of claim 30, wherein the display region comprises a second region; and
a density of first spacer portions in the second region is greater than or equal to a density of first spacer portions in the first region.

34. The display panel of claim 30, wherein in the first region, a density of first spacer portions is smaller than a density of third openings.

35. The display panel of claim 1, wherein the display region further comprises at least one metal layer located between the substrate and the light-blocking layer, and a metal layer of the at least one metal layer comprises a plurality of metal portions; and
along the first direction, a third opening of the at least one third opening does not overlap a metal portion of the plurality of metal portions.

36. The display panel of claim 35, wherein along a second direction, a distance from the third opening to the metal portion is greater than or equal to a first distance, wherein the second direction intersects with the first direction.

37. The display panel of claim 36, wherein the first distance is equal to 3 μm.

38. The display panel of claim 36, wherein the at least one metal layer comprises a first metal layer and a second metal layer; the second metal layer is located between the substrate and the first metal layer and comprises a plurality of second metal portions; and
along the second direction, a distance from the third opening to a second metal portion of the plurality of second metal portions is larger than the first distance.

39. The display panel of claim 38, wherein the first metal layer is located between the substrate and the pixel definition layer; or
the first metal layer is located between the pixel definition layer and the light-blocking layer.

40. The display panel of claim 35, wherein the at least one metal layer comprises a third metal layer located between the pixel definition layer and the light-blocking layer;
the third metal layer comprises a plurality of third metal portions, and at least one of the plurality of third metal portions each comprises a plurality of first meshes; and
along the first direction, at least one of the plurality of first meshes surrounds at least one of the plurality of light-emitting elements.

41. The display panel of claim 40, wherein the at least one of the plurality of third metal portions each comprises a plurality of second meshes; and
along the first direction, at least one of the plurality of second meshes surrounds the at least one third opening.

42. The display panel of claim 40, wherein the display region further comprises an encapsulation layer located between the pixel definition layer and the light-blocking layer; and
the third metal layer is located between the encapsulation layer and the light-blocking layer.

43. The display panel of claim 40, wherein the plurality of third metal portions comprise electrode portions and bridge portions; an electrode portion of the electrode portions comprises a first mesh of the plurality of first meshes, and at least two of the plurality of first meshes are electrically connected via a bridge portion of the bridge portions.

44. The display panel of claim 35, wherein the third opening comprises a third upper opening, a third lower opening, and a third inner sidewall connected between the third upper opening and the third lower opening;
along the first direction, the third lower opening is adjacent to the metal layer; and
along a second direction, a distance from the third lower opening to the metal portion is greater than or equal to a first distance, wherein the second direction intersects the first direction.

45. The display panel of claim 1, wherein the display region comprises a plurality of pixel circuits and a plurality of signal lines;
a pixel circuit of the plurality of pixel circuits comprises at least one transistor, and a transistor of the at least one transistor comprises a source and a drain;
the plurality of signal lines comprise a plurality of data signal lines, and a data signal line of the plurality of data signal lines is electrically connected to the source of the transistor of the at least one transistor or the drain of the transistor of the at least one transistor; and
in a plan view, a third opening of the at least one third opening between two adjacent ones of the plurality of data signal lines.

46. The display panel of claim 45, wherein the plurality of data signal lines extend along a first sub-direction and are arranged along a second sub-direction; the first sub-direction and the second sub-direction intersect and both intersect the first direction;
along the second sub-direction, the third opening comprises a first edge and a second edge that are opposite to each other; and
along the second sub-direction, a distance from any one of the first edge or the second edge to a most adjacent data signal line of the plurality of data signal lines is greater than or equal to a first distance.

47. The display panel of claim 1, wherein the display region comprises a plurality of pixel circuits and a plurality of signal lines;
a pixel circuit of the plurality of pixel circuits comprises at least one transistor, and a transistor of the at least one transistor comprises a gate;
the plurality of signal lines comprise a plurality of gate signal lines, and a gate signal line of the plurality of gate signal lines is electrically connected to the gate of the transistor of the at least one transistor; and
in a plan view, a third opening of the at least one third opening is adjacent to at least one of the plurality of gate signal lines.

48. The display panel of claim 47, wherein the plurality of gate signal lines extend along a second sub-direction and are arranged along a first sub-direction; the first sub-direction and the second sub-direction intersect and both intersect the first direction;
along the first sub-direction, the third opening comprises a third edge and a fourth edge that are opposite to each other; and
along the first sub-direction, a distance from any one of the third edge or the fourth edge to a most adjacent one of the plurality of gate signal lines is greater than or equal to a first distance.

49. The display panel of claim 3, wherein in the first region, the light-blocking layer further has at least one fourth opening, and the pixel definition layer has at least one fifth opening; and
along the first direction, the at least one fourth opening overlaps the at least one fifth opening and does not overlap the plurality of first openings.

50. The display panel of claim 49, wherein along the first direction, the at least one fourth opening does not overlap the color filters in the color filter layer and the plurality of light-emitting elements.

51. The display panel of claim 49, wherein in a plan view, an area of a fourth opening of the at least one fourth opening is less than or equal to an area of the third opening.

52. The display panel of claim 49, wherein the pixel definition layer comprises a plurality of first spacer portions; and
the at least one fourth opening does not overlap the plurality of first spacer portions along the first direction.

53. The display panel of claim 49, wherein a fourth opening of the at least one fourth opening is in a shape of a polygon or a circle.

54. The display panel of claim 49, wherein in a plan view, a fourth opening of the at least one fourth opening is located in a fifth opening of the at least one fifth opening.

55. The display panel of claim 49, wherein a fourth opening of the at least one fourth opening is configured to transmit light in a waveband centered at 550 nm; and
a third opening of the at least one third opening is configured to transmit light in a waveband centered at 940 nm.

56. The display panel of claim 2, wherein at least one of the first color filter, the second color filter, or the third color filter is each in a shape of a circle.

57. The display panel of claim 1, wherein a light-emitting element of the plurality of light-emitting elements comprises a first electrode, a second electrode, and a light-emitting layer located between the first electrode and the second electrode;
the first electrode is in a shape of a circle; and
along the first direction, the first electrode covers a first opening of the plurality of first openings.

58. A display device, comprising a display panel, wherein the display panel comprises a display region and a first region located within the display region,
wherein the display region comprises a substrate, a pixel definition layer, a plurality of light-emitting elements, and a light-blocking layer that are disposed sequentially; the pixel definition layer has a plurality of first openings, and the light-blocking layer has a plurality of second openings; the plurality of light-emitting elements are located in the plurality of first openings respectively;
wherein the light-blocking layer in the first region further has at least one third opening; and
wherein along a first direction, the plurality of second openings overlap the plurality of first openings respectively, and the at least one third opening does not overlap the plurality of first openings; the first direction is parallel to a stacking direction of film layers in the display region.
